(19) United States
(12) Patent Application Publication
(10) Pub. No.: US 2026/0353573 A1
(43) Pub. Date: Nov. 5, 2026

(54) SEQUENCER PACKAGING WITH INCLUSION OF SEPARATE CONNECTOR FOR GIGABIT ETHERNET

(71) Applicant: BAE Systems Information and Electronic Systems Integration Inc., Nashua, NH (US)

(72) Inventors: Danny L. Plemons, Austin, TX (US); Parker T. Hyink, Austin, TX (US); Christopher E. Kohl, Austin, TX (US); Jeffrey A. Gensler, Austin, TX (US); James M. Surge, Austin, TX (US)

(73) Assignee: BAE Systems Information and Electronic Systems Integration Inc., Nashua, NH (US)

(21) Appl. No.: 19/196,536

(22) Filed: May 1, 2025

(51) Int. Cl. H05K 5/00; B64D 7/00

(52) U.S. Cl. CPC H05K 5/0069; B64D 7/00; H05K 5/0052

(57) ABSTRACT

A sequencer for a countermeasure dispensing system. The sequencer includes a chassis, a top cover that operably engages with the chassis at a first position, a bottom cover that operably engages with the chassis at a second position, a chamber defined by the chassis, and a circuit card system (CCS). CCS operably engages with the chassis, the top cover, and the bottom cover and is substantially housed inside of the chamber and has a set of connectors. In the present disclosure, one connector of the set of connectors is an ethernet connector.

### STATEMENT OF GOVERNMENT INTEREST

This invention was made with government support under contract number N004212290009 awarded by the United States Navy. The government has certain rights in the invention.

### TECHNICAL FIELD

The present disclosure relates to a flexible circuit card assembly of a sequencer of a countermeasure dispensing system having ethernet capabilities.

### BACKGROUND ART

In current military technologies, military platforms, such as a military aircraft, include at least one countermeasure dispensing system (CMDS). The CMDS may eject one or more countermeasure expendables from the platform to dispense chaff material or flares away from the platform to counter a detected incoming threat, such as missiles or similar ballistic threats. Such dispensing of chaff material or flares away from the platform may then redirect the incoming threat away from the platform to leave the platform unscathed and/or unharmed. Each countermeasure dispenser in a CMDS is also electrically connected to a sequencer unit for ejecting the countermeasure expendables from the military platform. In operation, the sequencer unit is configured to eject one or more countermeasure expendables from at least one dispenser assembly based on commands received from a programmer of CMDS.

However, replacing or upgrading such legacy CMDSs, including legacy sequencers of CMDSs, in existing military aircraft is a difficult hurdle to combat. In most cases, military aircrafts are designed specifically around a specific CMDS that is advantageous for the aircraft when said aircraft was originally built. As such, updating or replacing one or more components of legacy CMDSs is rather costly and labor intensive based on the number of the components housed onboard the aircraft. Moreover, fitting a new CMDS that accommodates new features or capabilities into an existing military aircraft requires extensive hours of labor, extensive testing to ensure the new system is operational, and extreme costs to outfit such existing aircrafts.

### SUMMARY OF THE INVENTION

In one aspect, an exemplary embodiment of the present disclosure may provide a sequencer for a countermeasure dispensing system. The sequencer includes a chassis; a top cover operably engaged with the chassis at a first position; a bottom cover operably engaged with the chassis at a second position; a chamber collectively defined by the chassis, the top cover, and the bottom cover; and a circuit card system (CCS) operably engaged with the chassis and having a set of connectors; wherein one connector of the set of connectors is an ethernet connector.

This exemplary embodiment or another exemplary embodiment may further include an internal support housed inside of the chamber and supporting the CCS. This exemplary embodiment or another exemplary embodiment may further include that the CCS further comprises: a flexible control circuit card assembly (CCA) operably engaged with the chassis and the internal support. This exemplary embodiment or another exemplary embodiment may further include that the flexible control CCA comprises: a first circuit card operably engaged with the internal support at a first surface; and a second circuit card operatively engaged with the internal support at a second surface opposite to the first surface. This exemplary embodiment or another exemplary embodiment may further include that the flexible control CCA comprises: a third circuit card operably engaged with the chassis at a first location and is operable with a first pair of connectors of the set of connectors; and a fourth circuit card operably engaged with the chassis at a second location spaced apart from the first position of the third circuit card and is operable with a second pair of connectors of the set of connectors; wherein the ethernet connector is included in the second pair of connectors. This exemplary embodiment or another exemplary embodiment may further include that the first circuit card and the second circuit card are parallel to one another on the internal support; and wherein the third circuit card and the fourth circuit card are orthogonal to one another. This exemplary embodiment or another exemplary embodiment may further include that the control CCA further comprises: a set of flex connections operably engaging with the first circuit card, the second circuit card, the third circuit card, and the fourth circuit card; wherein the set of flex connections interconnects the first circuit card, the second circuit card, the third circuit card, and the fourth circuit card with one another. This exemplary embodiment or another exemplary embodiment may further include a set of alignment pins operably engaged with at least the internal support; and a set of alignment members formed in the chassis; wherein the set of alignment pins are configured to engage with the alignment members to align the internal support with the chassis. This exemplary embodiment or another exemplary embodiment may further include that the set of alignment pins are configured to engage with the first circuit card and the second circuit card to align the first circuit card and the second circuit card with the internal support. This exemplary embodiment or another exemplary embodiment may further include a power CCA operably engaged with the bottom cover and spaced apart from the internal support; wherein the power CCA and the flexible control CCA are operable with one another. This exemplary embodiment or another exemplary embodiment may further include that the ethernet connector is configured to output a broadband signal up to approximately one gigabit per second.

In another aspect, an exemplary embodiment of the present disclosure may provide a circuit card system (CCA) of a sequencer. The CCS includes an internal support housed inside of a chamber defined by the sequencer; a flexible control circuit card assembly (CCA) operably engaged with a chassis of the sequencer and the internal support; a power CCA operably engaged with a bottom cover of the sequencer and spaced apart from the internal support; and a set of connectors of the flexible control CCA; wherein one connector of the set of connectors is an ethernet connector; wherein the power CCA and the flexible control CCA are operable with one another.

This exemplary embodiment or another exemplary embodiment may further include that the flexible control CCA comprises: a first circuit card operably engaged with the internal support at a first surface; and a second circuit card operatively engaged with the internal support at a second surface opposite to the first surface. This exemplary embodiment or another exemplary embodiment may further include that the flexible control CCA comprises: a third circuit card operably engaged with the chassis at a first position and is operable with a first pair of connectors of the set of connectors; and a fourth circuit card operably engaged with the chassis at a second position orthogonal to the first position of the third circuit card and is operable with a second pair of connectors of the set of connectors; wherein the ethernet connector is included in the second pair of connectors. This exemplary embodiment or another exemplary embodiment may further include that the control CCA further comprises: a set of flex connections operably engaging with the first circuit card, the second circuit card, the third circuit card, and the fourth circuit card; wherein the set of flex connections interconnects the first circuit card, the second circuit card, the third circuit card, and the fourth circuit card with one another.

In yet another aspect, an exemplary embodiment of the present disclosure may provide a method of assembling a sequencer. The method includes steps of positioning a flexible control circuit card assembly (CCA) of a circuit card system (CCS) inside of a chassis of the sequencer, the flexible control CCA having a set of connectors; wherein one connector of the set of connectors is an ethernet connector; engaging a power CCA of the CCS with a bottom cover of the sequencer; engaging a top cover of the sequencer with the chassis; and engaging the bottom cover of the sequencer with the chassis.

This exemplary embodiment or another exemplary embodiment may further include steps of engaging a first circuit card of the flexible control CCA with an internal support of the sequencer at a first surface of the internal support; and engaging a second circuit card of the flexible control CCA with the internal support of the sequencer at a second surface of the internal support opposite to the first surface. This exemplary embodiment or another exemplary embodiment may further include steps of engaging a third circuit card of the flexible control CCA with the chassis at a first position and is operable with a first pair of connectors of the set of connectors; and engaging a fourth circuit card of the flexible control CCA with the chassis at a second position orthogonal to the first position of the third circuit card and is operable with a second pair of connectors of the set of connectors; wherein the ethernet connector is included in the second pair of connectors. This exemplary embodiment or another exemplary embodiment may further include a step of engaging a set of flex connections with the first circuit card, the second circuit card, the third circuit card, and the fourth circuit card; wherein the set of flex connections interconnects the first circuit card, the second circuit card, the third circuit card, and the fourth circuit card with one another. This exemplary embodiment or another exemplary embodiment may further include a step of engaging the top plate with the internal support and the flexible control CCA by a set of connectors.

### BRIEF DESCRIPTION OF THE DRAWINGS

Sample embodiments of the present disclosure are set forth in the following description, are shown in the drawings and are particularly and distinctly pointed out and set forth in the appended claims.

FIG. 1 is a diagrammatic view showing an aircraft having a countermeasure dispensing system (CMDS) used subsequent to detecting an incoming enemy threat.

FIG. 2 is a top, front, first side isometric perspective view of a sequencer of the CMDS in accordance with one aspect of the present disclosure.

FIG. 3A is a top, front, first side isometric perspective view of a top cover of the sequencer.

FIG. 3B is a top, front, first side isometric perspective view of a chassis of the sequencer.

FIG. 3C is a top, front, first side isometric perspective view of a control circuit card assembly (CCA) of a circuit card system (CCS) of the sequencer assembled on an internal support of the sequencer.

FIG. 3D is a top, front, first side isometric perspective view of a power CCA of the CCS of the sequencer and wiring of the sequencer.

FIG. 3E is a bottom, front, first side isometric perspective view of a bottom cover of the sequencer.

FIG. 4A is a first plan view of the control CCA in a first configuration.

FIG. 4B is a second plan view of the control CCA in the first configuration.

FIG. 4C is a top, front, first side isometric perspective view of the internal support of the sequencer.

FIG. 5 is a top, front, first side isometric perspective view of the control CCA operably engaged with the internal support, wherein the control CCA is in a second configuration.

FIG. 6A is an exploded view of the top cover, the chassis, the control CCA, and the internal support, wherein the control CCA is operably engaged with the internal support as shown in FIG. 5.

FIG. 6B is an exploded view of the bottom cover and the power CCA.

FIG. 7 is a top plan view of the sequencer shown in FIG. 2.

FIG. 8 is a sectional view of the sequencer taken in the direction of line 8-8 shown in FIG. 7.

FIG. 9 is a sectional view of the sequencer taken in the direction of line 9-9 shown in FIG. 7.

FIG. 10A is a partial sectional of the sequencer showing gaskets operably engaged with a first pair of connector of the control CCA and the chassis.

FIG. 10B is a partial sectional of the sequencer showing gaskets operably engaged with a second pair of connector of the control CCA and the chassis.

FIG. 11 is an electrical schematic diagram of the CCS.

FIG. 12 is an exemplary flowchart of a method.

FIG. 13 is a top, front, first side isometric perspective view of a sequencer of the CMDS in accordance with another aspect of the present disclosure.

FIG. 14A is a top, front, first side isometric perspective view of a top cover of the sequencer shown in FIG. 13.

FIG. 14B is a bottom, front, first side isometric perspective view of the top cover of the sequencer shown in FIG. 13.

FIG. 15 is a top, front, first side isometric perspective view of a chassis of the sequencer.

FIG. 16 is a top, front, first side isometric perspective view of a control circuit card assembly (CCA) of a circuit card system (CCS) of the sequencer assembled on internal supports of the sequencer shown in FIG. 13.

FIG. 17A is a top, front, first side isometric perspective view of a bottom cover of the sequencer shown in FIG. 13.

FIG. 17B is a bottom, front, first side isometric perspective view of the bottom cover of the sequencer shown in FIG. 13.

FIG. 18 is an exploded view of the CCA of CCS and internal supports, collectively, and a power CCA frame assembly of CCS.

FIG. 19 is a bottom, front, first side isometric perspective view of the power CCA frame assembly.

FIG. 20A is an exploded view of the power CCA frame assembly.

FIG. 20B is another exploded view of the power CCA frame assembly.

FIG. 21 is an exploded view of the internal supports of CCS.

Similar numbers refer to similar parts throughout the drawings.

### DETAILED DESCRIPTION

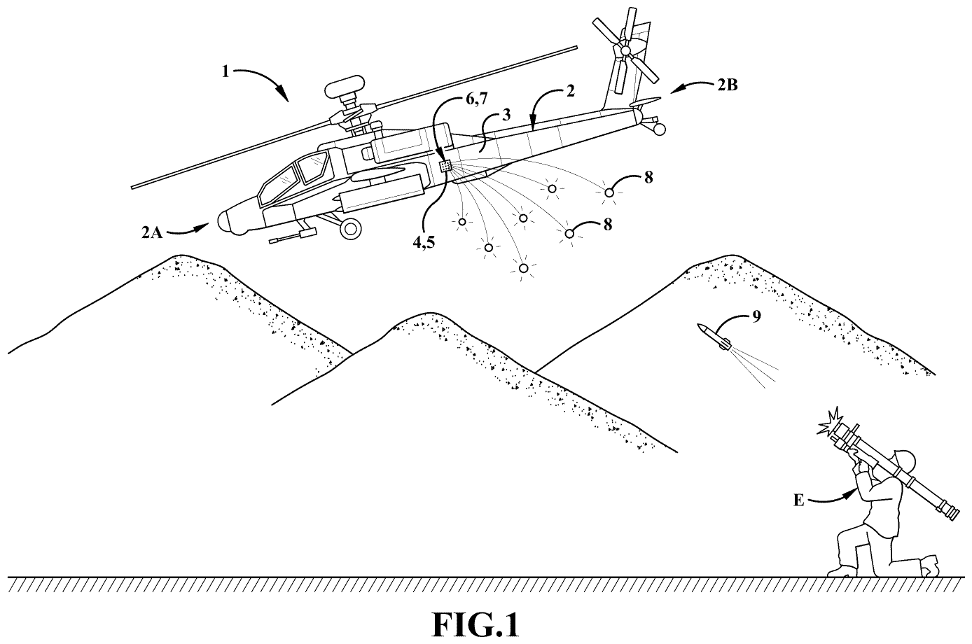

FIG. 1 illustrates a platform 1 such as a vehicle, ship or aircraft, which may be manned or unmanned, that includes a main body 2. As used herein, aircraft refers to fixed and rotary wing aircraft as well as UAVs and satellites. The main body 2 has a front end 2A and a rear end 2B longitudinally opposite to the front end 2A. It should be understood that the directions of “front,” “rear,” “top,” “bottom,” “right,” and “left” are only used as a directional reference for the main body 2 and its associated components and/or parts described herein and illustrated in FIG. 1.

The platform 1 in this example is an aircraft and includes a sidewall 3 that extends longitudinally between the front end 2A of the main body 2 and the rear end 2B of the main body 2. The sidewall 3 defines an opening 4 that is disposed between the front and rear ends 2A, 2B of the main body 2 providing access to a chamber 5. The opening 4 and the chamber 5 defined by the sidewall 3 is sized and configured to receive a countermeasure dispensing system 6 (“CMDS”). The CMDS 6 operably engages the sidewall 3 of the main body 2 to mechanically fix the CMDS 6 to the platform 1. As illustrated in FIG. 1, the CMDS 6 is in line with the sidewall 3 of the main body 2 such that the CMDS 6 is even with the mold line of the platform 1 for aerodynamic purposes. Upon mounting the CMDS 6, the CMDS 6 is electrically connected to a legacy wiring harness (not illustrated) that is provided in the platform 1 to provide power and communication to some or all electrical components in the CMDS 6, which is described in more detail below.

Prior to military operation or an aerial mission of the platform 1, the CMDS is pre-loaded with a plurality of expendables 7. Each expendable of the plurality of expendables 7 is loaded with flare and/or chaff material 8 for countermeasure purposes. In addition, each expendable of the plurality of expendables 7 includes an impulse cartridge (not illustrated) for detonating and dispensing the expendable from the platform 1. During military operation, the flare and/or chaff material 8 provides a distraction to an incoming enemy threat 9, initiated by an enemy “E”, where the incoming enemy threat 9 is diverted to the flare and/or chaff material 8 while allowing the platform 1 to remain unscathed. During military operation or an aerial mission, the platform 1 may receive a warning from an on-board electronic warfare (EW) system regarding the incoming enemy threat 9 approaching the platform 1. Upon a determination made by the on-board EW system and/or an operator, the CMDS 6 dispenses a calculated amount of expendables of the plurality of expendables 7 that are disposed underneath, behind, or to the side of the platform 1. In addition, the CMDS 6 may also be provided along any suitable location of the platform 1 other than sidewall 3 of the main body 2. In one exemplary embodiment, a CMDS may be provided within a wing of an aircraft. In another exemplary embodiment, a CMDS may be provided in a fuselage or a pod disposed on an aircraft.

It should be understood that the CMDS 6 is logically powered and controlled by an on-board system. The system may include suitable devices and apparatuses that are operably engaged with one another to logically control and power the CMDSs (such as CMDS 6) described and illustrated herein. In the illustrated embodiments, CMDSs described and illustrated herein may be logically powered and controlled by a legacy on-board system retaining a majority of legacy devices and apparatuses that are operably engaged with and in communication with one another. Examples of legacy devices and apparatuses that may be provided in this system include, but not limited to, a cockpit interface, discrete components, serial buses, a programmer, and data links. In another instance, a CMDS described and illustrated herein may be logically powered and controlled by a new on-board system having new devices and apparatuses that are operably engaged with one another.

Moreover, it will be understood that the on-board system may also retain and use legacy components of legacy CMDSs currently available. In one instance, a CMDS described and illustrated herein may maintain a legacy dispenser along with a legacy wiring harness operably engaging the CMDS with the legacy on-board system. In another instance, a CMDS described and illustrated herein may only maintain a legacy wiring harness operably engaging the CMDS with the legacy on-board system. Furthermore, it will be understood that CMDSs described and illustrated herein may also use new components that are not legacy to an aircraft nor a legacy on-board system provided on the aircraft. Such use of legacy and/or new components of CMDSs are described in further details below.

Furthermore, it will be understood that CMDS 6 may include conventional and/or known devices and apparatuses for ejecting and dispensing one or more countermeasure expendables from platform 1. As such, CMDS 6 may include dispensers or dispenser assemblies, breechplates, magazines, and other suitable devices or apparatuses conventionally needed for ejecting and dispensing one or more countermeasure expendables from platform 1.

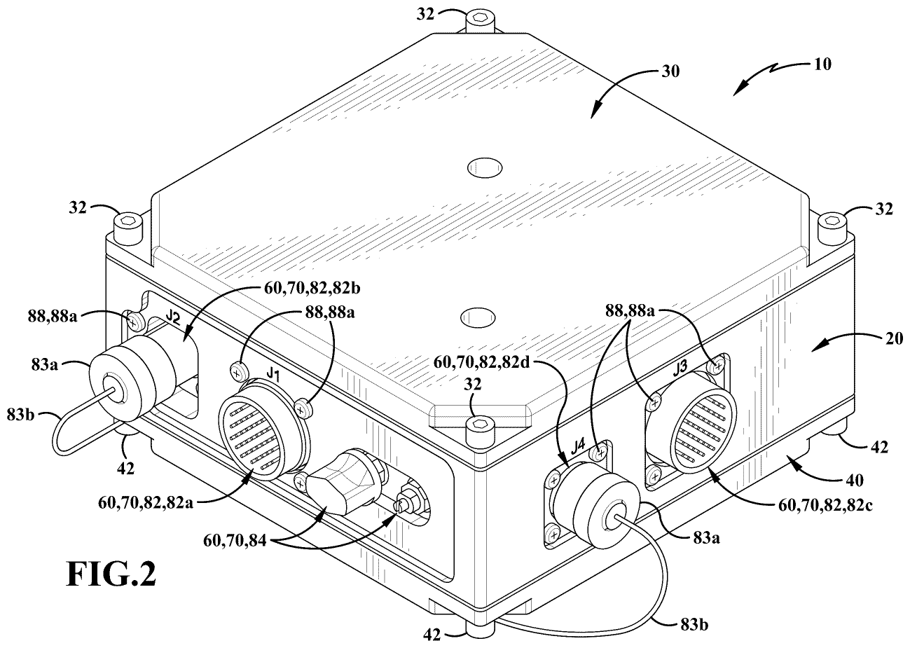

CMDS 6 includes a sequencer 10 (see FIG. 2). In the present disclosure, sequencer 10 is configured to communicate between a programmer or similar on-board device of CMDS 6 and one or more dispensers of CMDS 6 equipped to platform 1. As discussed in greater detail below, sequencer 10 includes a new structural configuration for housing necessary circuit card components and devices as well as the option of using ethernet-based or Internet capable devices with sequencer 10. Such components and elements of sequencer 10 are now discussed in greater detail below.

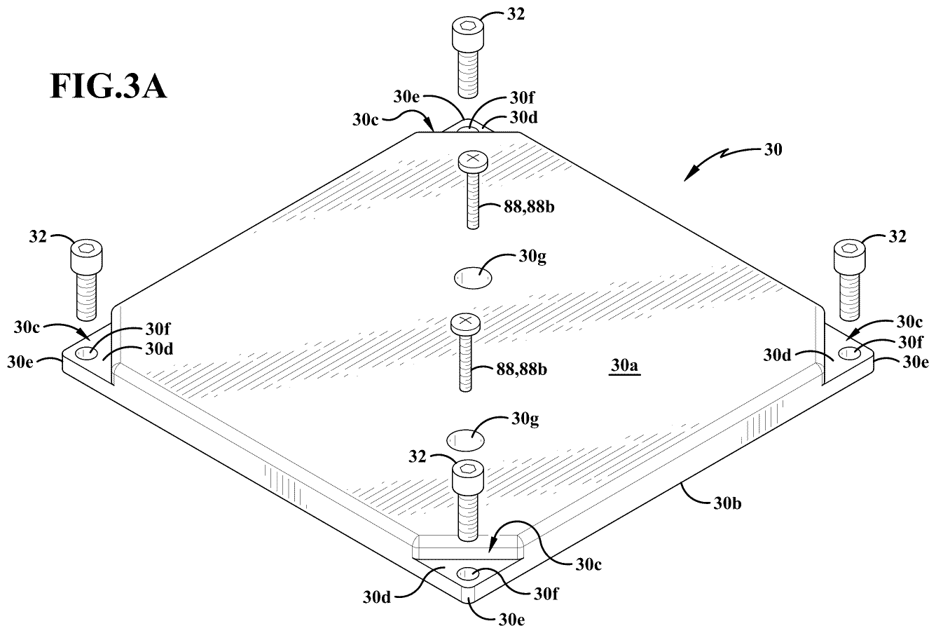

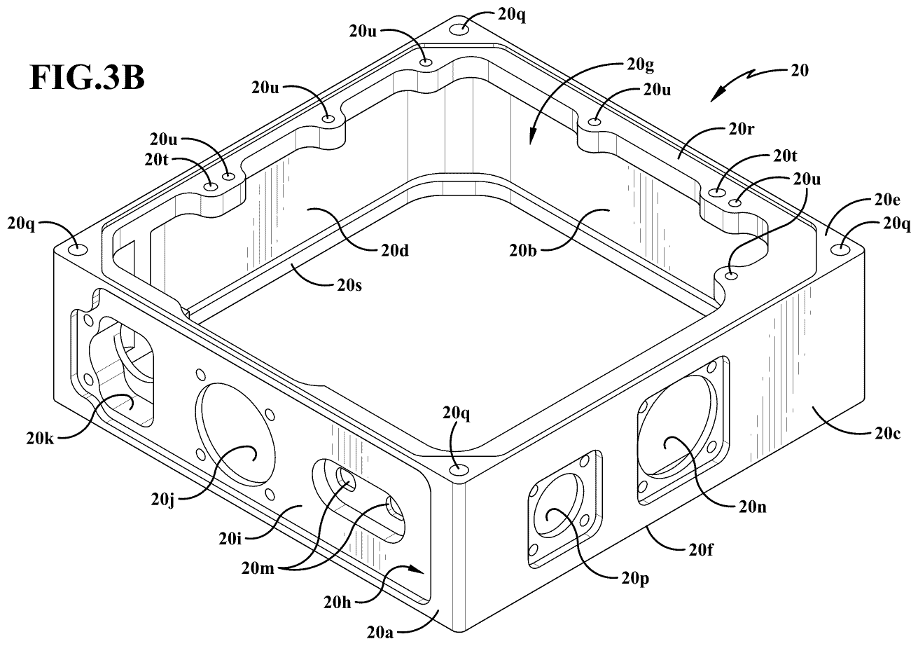

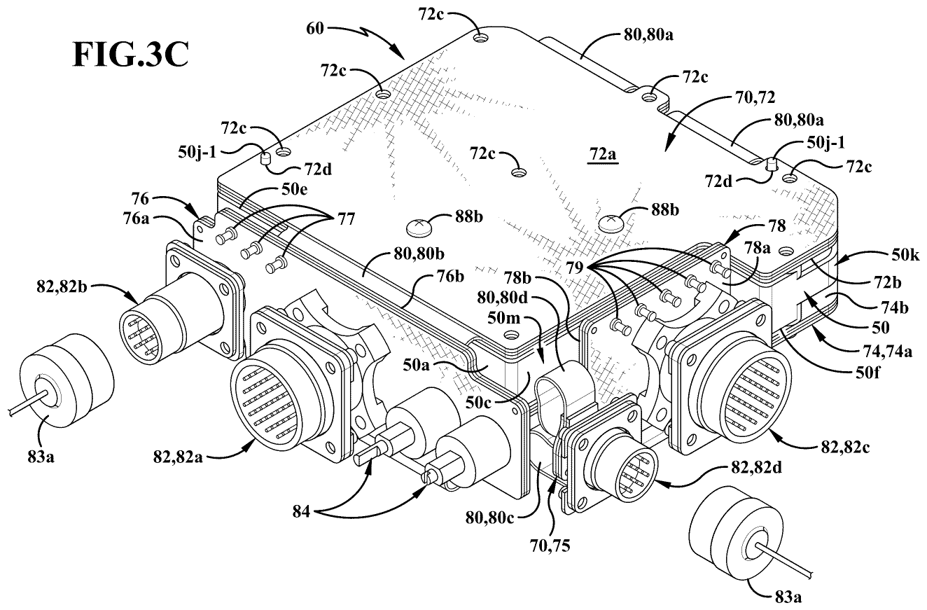

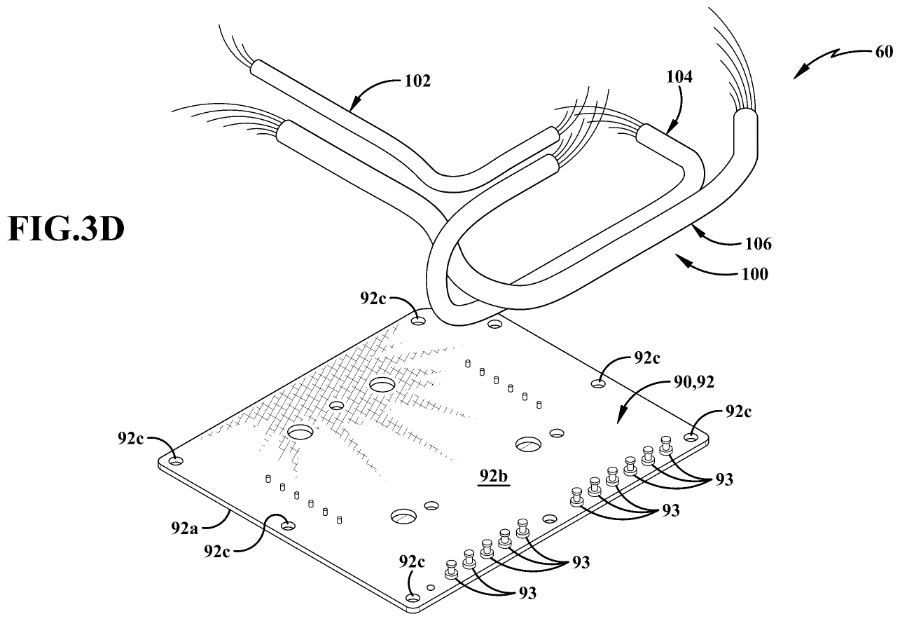

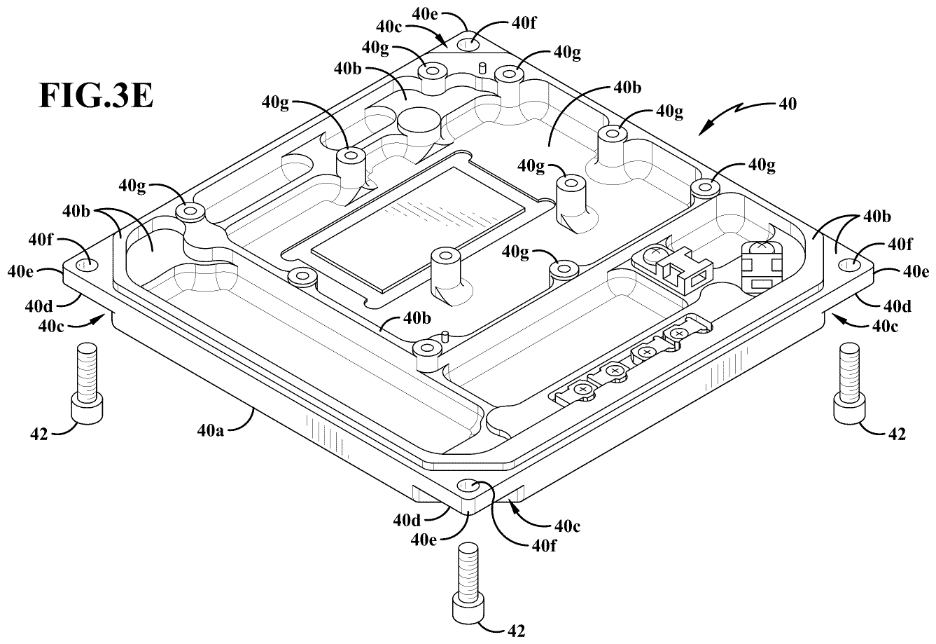

Sequencer 10 includes a chassis 20. As best seen in FIG. 3B, chassis 20 includes a first or front wall 20a, a second or rear wall 20b that is opposite to the front wall 20a, and a first axis defined between the front wall 20a and the second wall 20b. Chassis 20 also includes a first side wall 20c, a second side wall 20d that is opposite to the first side wall 20c, and a second axis defined between the first side wall 20c and the second side wall 20d; the second axis is orthogonal to the first axis of the chassis 20. Chassis 20 also includes a top end 20e that is collectively defined by the front wall 20a, the rear wall 20b, the first side wall 20c, and the second side wall 20d, a bottom end 20f that is collectively defined by the front wall 20a, the rear wall 20b, the first side wall 20c, and the second side wall 20d and is opposite to the top end 20e, and a third axis defined between the top end 20e and the bottom end 20f.

Still referring to FIG. 3B, chassis 20 also defines a chamber 20g. Particularly, chamber 20g is collectively defined by the front wall 20a, the rear wall 20b, the first side wall 20c, the second side wall 20d, the top end 20e, and the bottom end 20f. In the present disclosure, chamber 20g is accessible from the top end 20e or the bottom end 20f due to top end 20e and the bottom end 20f each being an open end. Such use and purpose of chamber 20g is discussed in greater detail below.

Chassis 20 also defines a front recess 20h that extends into the chassis 20 from the front wall 20a to a base wall 20i. Inside of the front recess 20h, a first opening 20j and a second opening 20k are each defined in the base wall 20i of front wall 20a in which the first opening 20j and the second opening 20k are adjacent to one another along an axis that is parallel to the second axis of chassis 20. Inside of front recess 20h, a pair of recessed apertures 20m is also defined in the base wall 20i of front wall 20a; the pair of recessed apertures 20m is also defined adjacent to the second opening 20k along an axis that is parallel to the second axis of chassis 20. In the present disclosure, the second opening 20k is located between the first opening 20j and the pair of recessed apertures 20m on the front wall 20a. Such use and purpose of the first opening 20j, the second opening 20k, and the pair of apertures 20m are discussed in greater detail below.

Still referring to FIG. 3B, chassis 20 also defines a third opening 20n and a fourth opening 20p that are each recessed into the first side wall 20c. Similar to the first opening 20j and the second opening 20k, the third opening 20n and the fourth opening 20p are adjacent to one another along an axis that is parallel to the first axis of chassis 20. Such use and purpose of the third opening 20n and the fourth opening 20p are discussed in greater detail below.

Still referring to FIG. 3B, chassis 20 also defines pairs of attachment openings 20q. In the present disclosure, each pair of attachment openings 20q is defined near a corner or an intersection point between two intersecting walls of chassis 20. In one example, a first attachment opening of a pair of attachment openings 20q extends downwardly from the top end 20e and into the chassis 20 at a corner or an intersection point between two intersecting walls 20a, 20b, 20c, 20d of chassis 20. Similarly, a second attachment opening of the same pair of attachment openings 20q extends upwardly from the bottom end 20f and into the chassis 20 at the same corner or same intersection point between two intersecting walls 20a, 20b, 20c, 20d of chassis 20. The first and second attachment openings of the pair of attachment openings 20q are aligned with one another but receive different connectors to secure a top cover with the chassis 20 or a bottom cover with the chassis 20, which are discussed in greater detail below.

Chassis 20 also includes an upper attachment flange 20r and a lower attachment flange 20s. As best seen in FIG. 3B, upper attachment flange 20r and lower attachment flange 20s each extends into the chamber 20g from the front wall 20a, the rear wall 20b, the first side wall 20c, and the second side wall 20d. In the present disclosure, the upper attachment flange 20r is located at the top end 20e of chassis 20, and the lower attachment flange 20s is located at the bottom end 20f of chassis 20 that is vertically opposite to the upper attachment flange 20r. Upper attachment flange 20r also includes a set of alignment members 20t that is positioned along the perimeter of upper attachment flange 20r. Upon assembly, each alignment member of the set of alignment members 20t is configured to receive an alignment pin or connector of a circuit card system of sequencer 10, which is discussed in greater detail below. Upper attachment flange 20r also defines a set of securement holes 20u that is positioned along the perimeter of upper attachment flange 20r. Upon assembly, each securement hole of the set of securement holes 20u is configured to receive a connector of a circuit card system of sequencer 10 so that the connector operably engages with the upper attachment flange 20r, which is discussed in greater detail below.

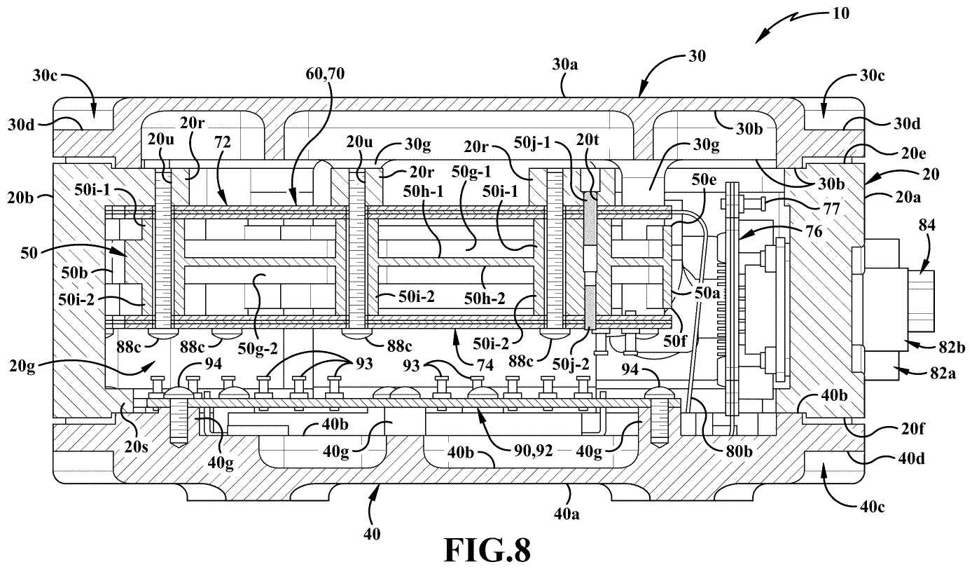

Sequencer 10 also includes a top cover 30 that operably engages with chassis 20 at the top end 20e. As best seen in FIG. 3A, top cover 30 includes an exterior surface 30a, an inner surface 30b that is opposite to the exterior surface 30a and operably engages with the top end 20e of chassis 20 (see FIGS. 2 and 8), and a vertical axis defined between the exterior surface 30a and the inner surface 30b. In the present disclosure, top cover 30 protects and shields the chamber 20g of chassis 20 from the top end 20e when the top cover 30 operably engages with the chassis 20.

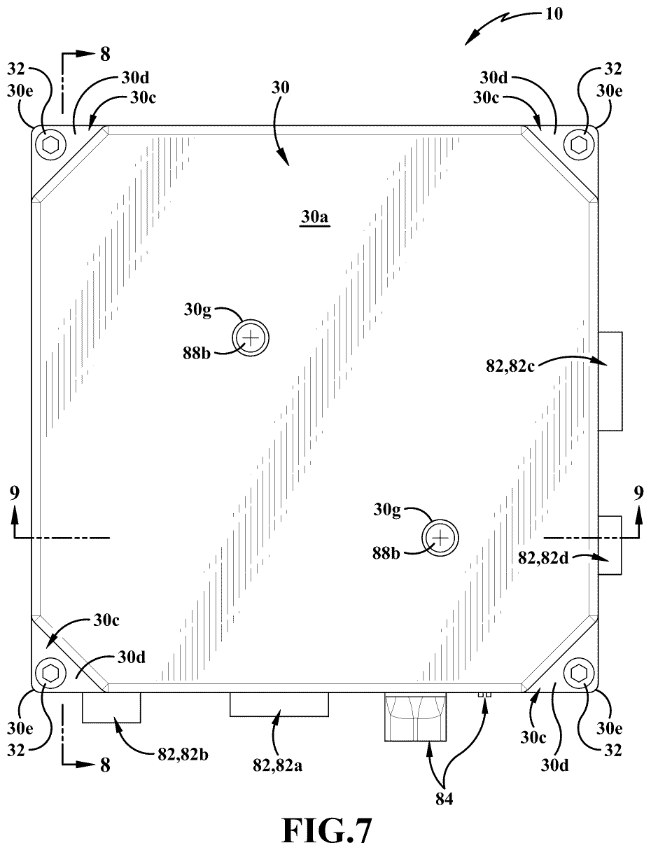

Top cover 30 also defines a set of recesses 30c. As best seen in FIG. 3A, each recess of the set of recesses 30c extends downwardly from the exterior surface 30a to a respective base wall 30d. Each recess of the set of recesses 30c is also defined at a respective corner 30e of top cover 30 since top cover 30 has a substantially rectangular shape when viewed from a top plan view (see FIG. 7). In other exemplary embodiments, each recess of a set of recesses of a top cover discussed herein may be defined at any position along the top cover. Top cover 30 also defines a set of securement apertures 30f where a securement aperture of the set of securement apertures 30f is defined inside a respective recess 30c and at a respective corner 30e. Upon assembly, a securement aperture of the set of securement apertures 30f is aligned with a respective attachment opening of the pairs of attachment opening 20q defined at the top end 20e of chassis 20. With such alignment, a first set of fasteners 32 may operably engage the top cover 30 with the chassis 20 at the set of securement apertures 30f and at the pairs of attachment opening 20q at the top end 20e.

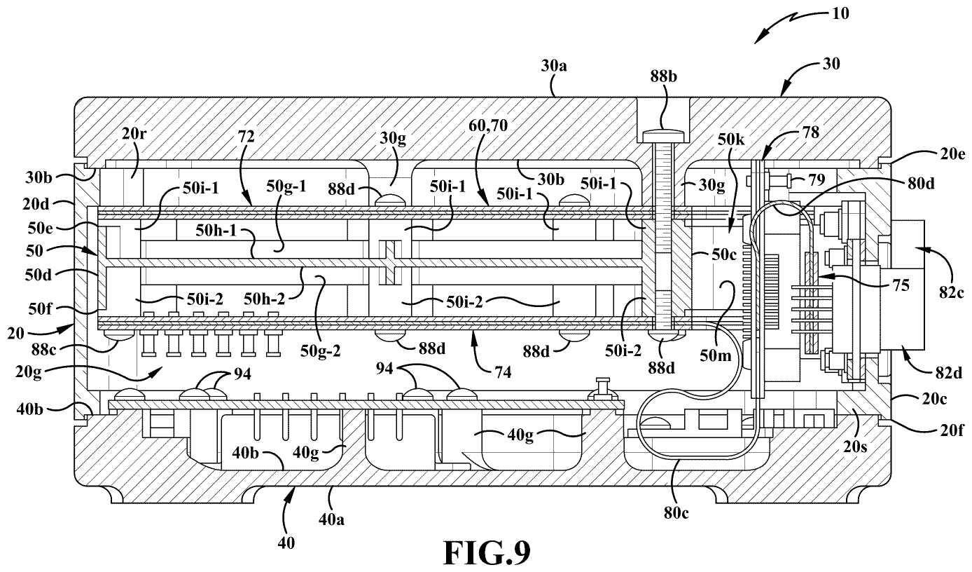

Top cover 30 also includes a set of standoffs 30g. As best seen in FIG. 9, each standoff of the set of standoffs 30g extends downwardly from the inner surface 30b. Each standoff of the set of standoffs 30g is also located at a position internally to the set of securement apertures 30f. As discussed in greater detail below, the set of standoffs 30g is configured to receive and house a portion of a fastener of a set of fasteners to engage the top cover 30 with a control circuit card assembly of a circuit card system of the sequencer 10.

Sequencer 10 also includes a bottom cover 40 that operably engages with chassis 20 at the bottom end 20f. As best seen in FIG. 3E, bottom cover 40 includes an exterior surface 40a, an inner surface 40b that is opposite to the exterior surface 40a and operably engages with the bottom end 20f of chassis 20 (see FIGS. 2 and 8), and a vertical axis defined between the exterior surface 40a and the inner surface 40b. In the present disclosure, bottom cover 40 protects and shields the chamber 20g of chassis 20 from the bottom end 20f when the bottom cover 40 operably engages with the chassis 20.

Bottom cover 40 also defines a set of recesses 40c. As best seen in FIG. 3E, each recess of the set of recesses 40c extends upwardly from the exterior surface 40a to a respective base wall 40d. Each recess of the set of recesses 40c is also defined at a respective corner 40e of bottom cover 40 since bottom cover 40 has a substantially rectangular identical to the top cover 30. In other exemplary embodiments, each recess of a set of recesses of a bottom cover discussed herein may be defined at any position along the bottom cover. Bottom cover 40 also defines a set of securement apertures 40f where a securement aperture of the set of securement apertures is defined inside a respective recess 40c and at a respective corner 40e. Upon assembly, a securement aperture of the set of securement apertures 40f is aligned with a respective attachment opening of the pairs of attachment opening 20q defined at the bottom end 20f of chassis 20. With such alignment, a second set of fasteners 42 may operably engage the bottom cover 40 with the chassis 20 at the set of securement apertures 40f and at the pairs of attachment opening 20q at the bottom end 20f.

Bottom cover 40 also includes a set of standoffs 40g. As best seen in FIG. 9, each standoff of the set of standoffs 40g extends from the inner surface 40b. Each standoff of the set of standoffs 40g is also located at a position internally to the set of securement apertures 40f. As discussed in greater detail below, the set of standoffs 40g is configured to receive and house a portion of a fastener of another set of fasteners to engage the bottom cover 40 with a control circuit card assembly of a circuit card system of the sequencer 10, which are discussed in greater detail below.

Sequencer 10 also includes an internal support or stiffener 50 that operably engages with the chassis 20 and the top cover 30. As discussed in greater detail below, internal support 50 is configured to support and maintain a control circuit card assembly of a circuit card system of sequencer 10 when the sequencer 10 is assembled. Such elements of internal support 50 are now discussed in greater detail below.

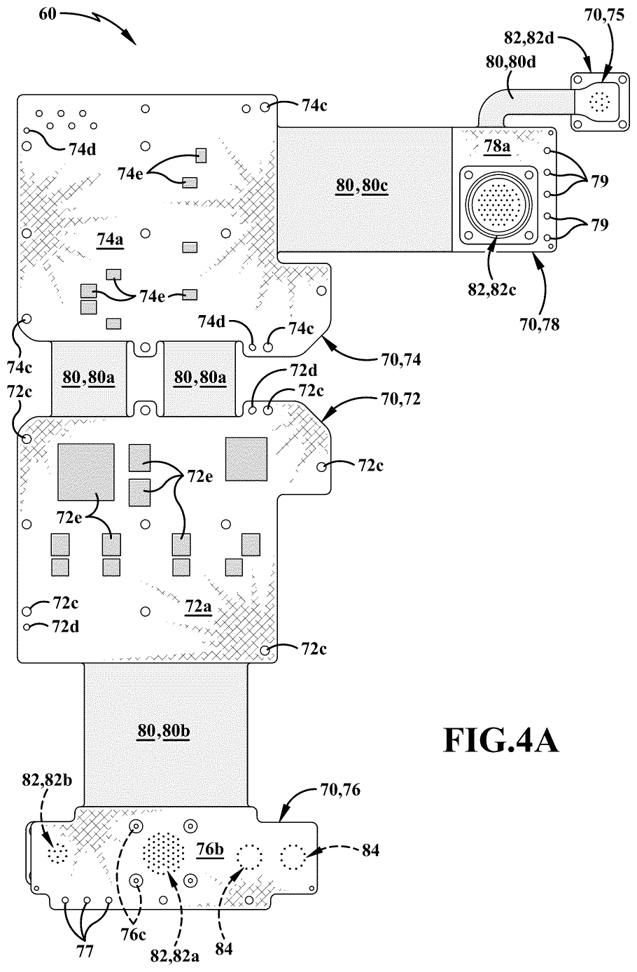

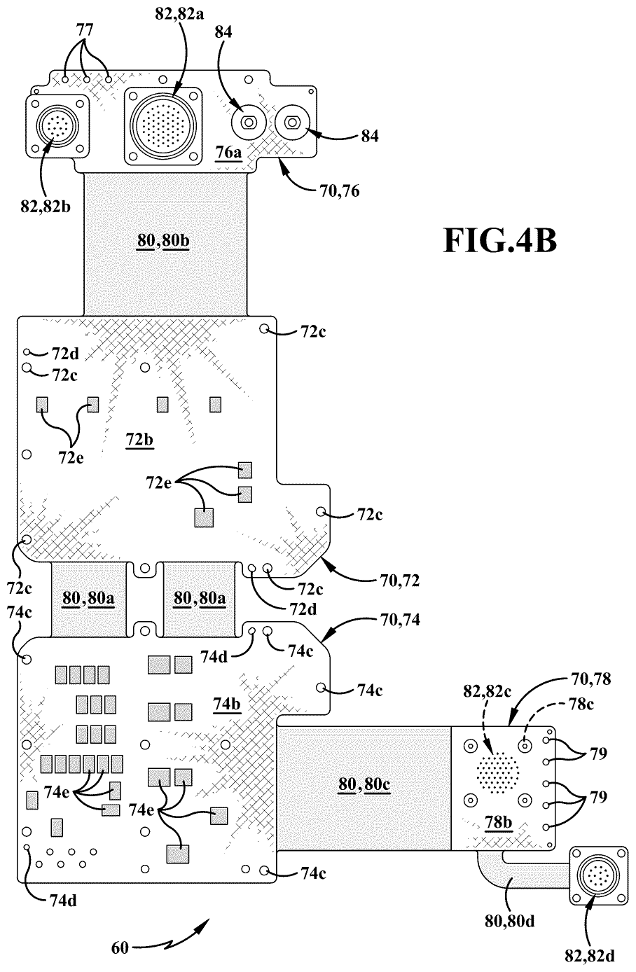

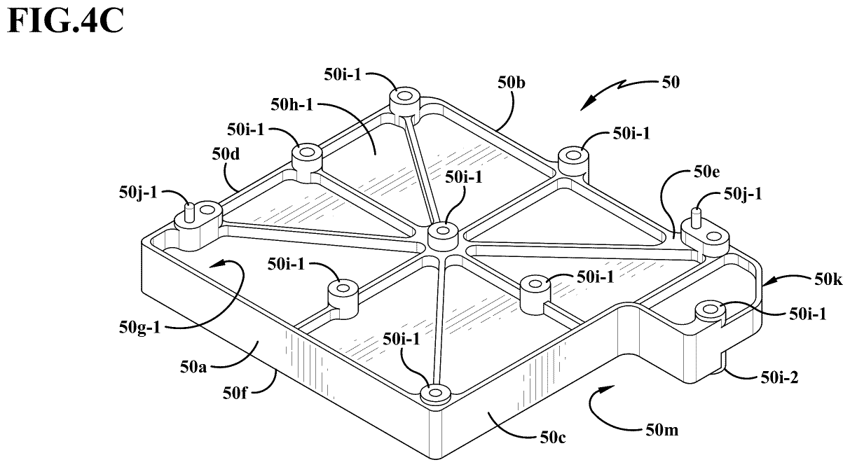

As best seen in FIG. 4C, internal support 50 includes a first or front wall 50a, a second or rear wall 50b that is opposite to the front wall 50a, and a first axis defined between the front wall 50a and the second wall 50b. Internal support 50 also includes a first side wall 50c, a second side wall 50d that is opposite to the first side wall 50c, and a second axis defined between the first side wall 50c and the second side wall 50d; the second axis is orthogonal to the first axis of the internal support 50. Internal support 50 also includes a top end 50e that is collectively defined by the front wall 50a, the rear wall 50b, the first side wall 50c, and the second side wall 50d, a bottom end 50f that is collectively defined by the front wall 50a, the rear wall 50b, the first side wall 50c, and the second side wall 50d and is opposite to the top end 50e, and a third axis defined between the top end 50e and the bottom end 50f.

Still referring to internal support 50, internal support 50 also defines a first set of recesses 50g-1 and a second set of recesses 50g-2. As best seen in FIG. 4C, each recess of the first set of recesses 50g-1 extends downwardly from the top end 50e to a respective base wall of a first set of base walls 50h-1. Similarly, and as best seen in FIG. 8, the second set of recesses 50g-2 extends upwardly from the bottom end 50f to a respective base wall of a second set of base walls 50h-2. With such sets of recesses 50g-1, 50g-2, a set of cross-members or braces are formed in the internal support that extend from a central point of the internal support 50 to a respective wall 50 a, 50 b, 50 c, 50 d of internal support 50 (see FIG. 4C).

Still referring to internal support 50, internal support 50 also includes a first set of standoffs 50i-1 and a second set of standoffs 50i-2. As best seen in FIG. 4C, each standoff of the first set of standoffs 50i-1 extends outwardly from a respective base wall of the first set of base walls 50h-1 and past the top end 50e of the internal support 50. Similarly, and as best seen in FIG. 8, each standoff of second set of standoffs 50i-2 extends outwardly from a respective base wall of the second set of base walls 50h-2 and past the bottom end 50f of the internal support 50. In one instance, and as discussed in greater detail below, a bolt or connector may pass through a standoff of the first set of standoffs 50i-1 and a standoff of the second set of standoffs 50i-2 that are aligned with one another to engage the internal support 50 and a control circuit card assembly with one another (see FIG. 9). In another instance, and as discussed in greater detail below, another bolt or connector may pass through a standoff of the first set of standoffs 50i-1 and a standoff of the second set of standoffs 50i-2 that are aligned with one another to engage the chassis 20, the internal support 50, and a control circuit card assembly with one another (see FIG. 8).

Still referring to internal support 50, internal support 50 also includes a first set of alignment pins 50j-1 and a second set of alignment pins 50j-2. As best seen in FIG. 4C, each alignment pin of the first set of alignment pins 50j-1 extends outwardly from the top end 50e of internal support 50. Similarly, and as best seen in FIG. 8, each alignment pin of the second set of alignment pins 50j-2 extends outwardly from the bottom end 50f of internal support 50. It will be understood that an alignment pin of the first set of alignment pins 50j-1 is aligned with an alignment pin of the second set of alignment pins 50j-2 (see FIG. 8). Upon assembly, and as discussed in greater detail below, the first set of alignment pins 50j-1 are received by a first circuit card of a control circuit card assembly so that said first circuit card is aligned correctly with the internal support 50 prior to connectors operably engaging said first circuit card with the internal support 50. Similarly, the second set of alignment pins 50j-2 are received by a second circuit card of the control circuit card assembly so that said second circuit card is aligned correctly with the internal support 50 prior to connectors operably engaging said second circuit card with the internal support 50.

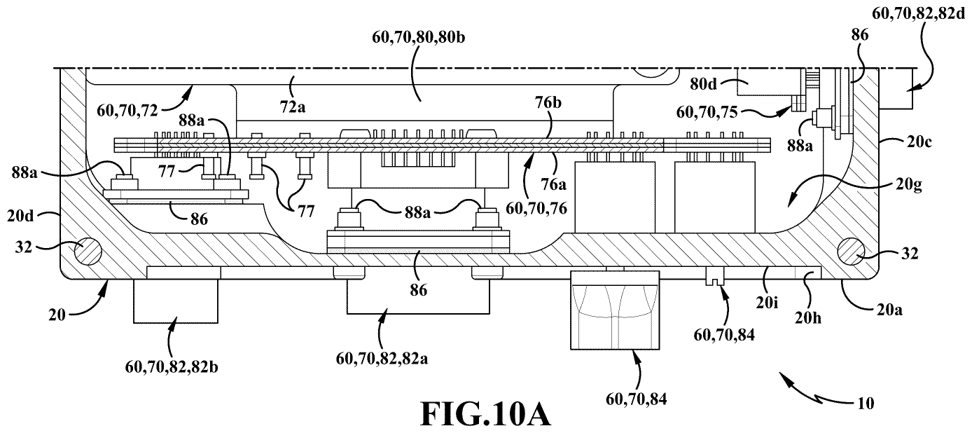

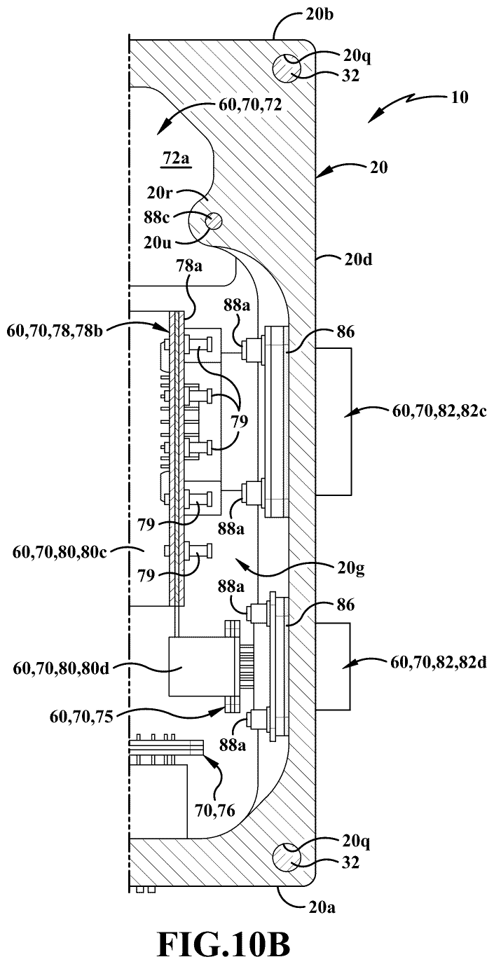

Internal support 50 also includes an extension 50k. As best seen in FIG. 4C, extension 50k protrudes outwardly from the rear wall 50b and the first side wall 50c. It will be understood that extension 50k may further define and be an addition to the top end 50e and the bottom end 50f for engaging one or more circuit cards of a control circuit card assembly of the sequencer 10, which is discussed in greater detail below. Extension 50k also includes a standoff from the first set of standoffs 50i-1 and a standoff from the second set of standoffs 50i-2 for engaging one or more circuit cards of a control circuit card assembly of the sequencer 10. Additionally, a compartment 50m is defined collectively by the first side wall 50c and the extension 50k. Upon assembly of sequencer 10, a portion of a circuit card of the control circuit card assembly is housed inside of the compartment 50 m (see FIG. 10B).

As mentioned briefly above, sequencer 10 includes a circuit card system (hereinafter “CCS”) that is generally referred to as 60 in FIGS. 3C-3D. CCS 60 includes necessary electrical components and elements in order to transmit and receive information between a programmer of CMDS 6 and one or more dispensers of CMDS 6. Such components of CCS 60 are now discussed in greater detail below.

CCS 60 includes a control circuit card assembly (hereinafter “control CCA”) that is generally referred to as 70 in FIGS. 4A-4B. Control CCA 70 includes a first circuit card 72 that operably engages with the internal support 50 at the top end 50e. In the present disclosure, first circuit card 72 includes an outer surface 72a that is spaced apart from the internal support 50 when sequencer 10 is assembled, and an inner surface 72b that is opposite to the outer surface 72a and operably engages with the top end 50e of internal support 50. In the present disclosure, first circuit card 72 may also include an extension or projection that matches the extension 50k of internal support 50 where the extension and a side wall of first circuit card (aligned with first side wall 50c) defines a compartment similar to compartment 50m of internal support 50 (see FIG. 3C). With such matching structural configuration, a portion of a fourth circuit card of the CCA 70 may nest inside of the compartment 50m defined by internal support and the compartment defined by the first circuit card 72

First circuit card 72 also defines a first set of securement apertures 72c that extends entirely through the first circuit card 72 between the outer surface 72a and the inner surface 72b (see FIGS. 4A-4B). Upon assembly, each securement aperture of the first set of securement apertures 72c is configured to receive and house a portion of a connector so that first circuit card 72 may be secured to the internal support 50 at the top end 50e. First circuit card 72 also defines a first set of alignment apertures 72d that extends entirely through the first circuit card 72 between the outer surface 72a and the inner surface 72b (see FIGS. 4A-4B). Upon assembly, each alignment aperture of the first set of alignment apertures 72d is configured to receive and house the first set of alignment pins 50j-1 so that the first circuit card 72 is aligned with the internal support 50 in the correct orientation.

First circuit card 72 also includes a plurality of circuity components 72e. In the present disclosure, the plurality of circuity components 72e is configured to transmit one or more logic signals from the sequencer 10 to a programmer of CMDS 6 or one or more dispensers of CMDS 6 during countermeasure operations. Additionally, the plurality of circuit components 72e is also configured to transmit one or more logic signals to other circuit card or circuity components of CCA 70 or CCS 60 depending during countermeasure operations.

Control CCA 70 also includes a second circuit card 74 that operably engages with the internal support 50 at the bottom end 50f. In the present disclosure, second circuit card 74 includes an outer surface 74a that is spaced apart from the internal support 50 when sequencer 10 is assembled, and an inner surface 74b that is opposite to the outer surface 74a and operably engages with the bottom end 50f of internal support 50. In the present disclosure, second circuit card 74 may also include an extension or projection that matches the extension 50k of internal support 50 where the extension and a side wall of first circuit card (aligned with first side wall 50c) defines a compartment similar to compartment 50m of internal support 50 (see FIG. 3C). With such matching structural configuration, a portion of a fourth circuit card of the CCA 70 may nest inside of the compartment 50m defined by internal support and the compartment defined by the second circuit card 74.

Second circuit card 74 also defines a second set of securement apertures 74c that extends entirely through the second circuit card 74 between the outer surface 74a and the inner surface 74b (see FIGS. 4A-4B). Upon assembly, each securement aperture of the second set of securement apertures 74c is configured to receive and house a portion of a connector so that second circuit card 74 may be secured to the internal support 50 at the bottom end 50f. Second circuit card 74 also defines a second set of alignment apertures 72d that extends entirely through the second circuit card 74 between the outer surface 74a and the inner surface 74b (see FIGS. 4A-4B). Upon assembly, each alignment aperture of the second set of alignment apertures 74d is configured to receive and house the second set of alignment pins 50j-2 so that the second circuit card 74 is aligned with the internal support 50 in the correct orientation.

Second circuit card 74 also includes a plurality of circuity components 74e. In the present disclosure, the plurality of circuity components 74e is configured to transmit one or more logic signals from the sequencer 10 to a programmer of CMDS 6 or one or more dispensers of CMDS 6 during countermeasure operations. Additionally, the plurality of circuit components 74e is also configured to transmit one or more logic signals to other circuit card or circuity components of CCA 70 or CCS 60 depending during countermeasure operations, including first circuit card 72.

Control CCA 70 also includes a third circuit card 76 that operably engages with the chassis 20 at the front wall 20a. In the present disclosure, third circuit card 76 includes an outer surface 76a that faces the first wall 20a of chassis 20 when sequencer 10 is assembled, and an inner surface 76b that is opposite to the outer surface 76a and faces the front wall 50a of internal support 50. As best seen in FIG. 8, the third circuit card 76 is positioned between the front wall 20a of the chassis 20 and the front wall 50a of the internal support 50.

Third circuit card 76 also defines a set of attachment holes 76c that extends entirely through the third circuit card 76 between the outer surface 76a and the inner surface 76b. Upon assembly, each attachment hole of the set of attachment holes 76c is configured to receive and house a portion of a connector so that third circuit card 76 may be secured to a first pair of connectors of the control CCA 70 that engages the third circuit card 76 with the chassis 20; such first pair of connectors of the control CCA 70 are discussed in greater detail below.

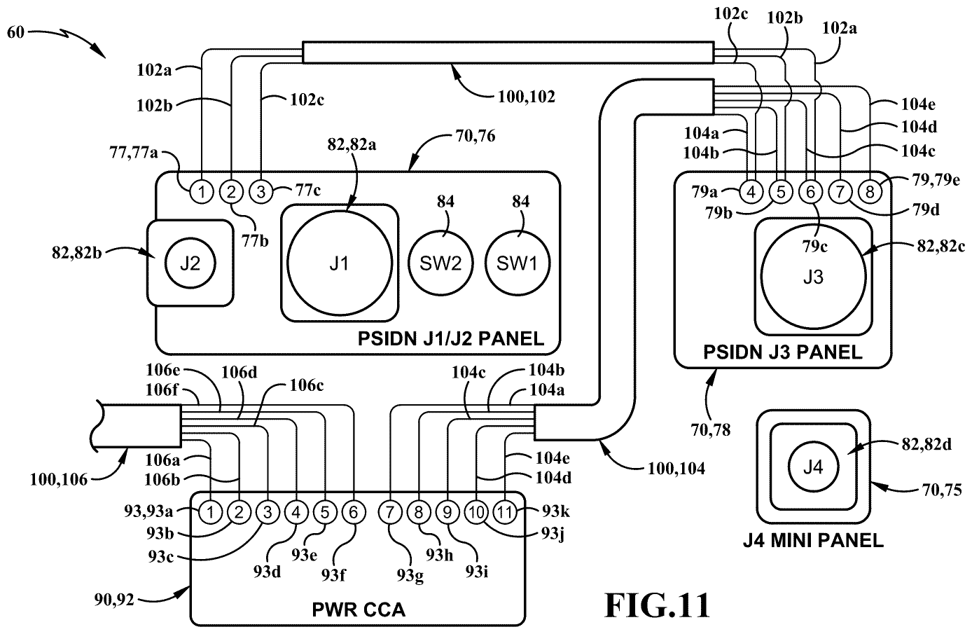

Third circuit card 76 also includes a set of terminals 77. As diagrammatically shown in FIG. 11, the set of terminals 77 includes a first terminal 77a that is operable for 28V logic out signals, a second terminal 77b that is operable for 28V return signals, and a third terminal 77c that is operable for chassis ground. It is understood a wire of a wiring harness connects with the set of terminals 77 to connect with the fourth circuit card 78.

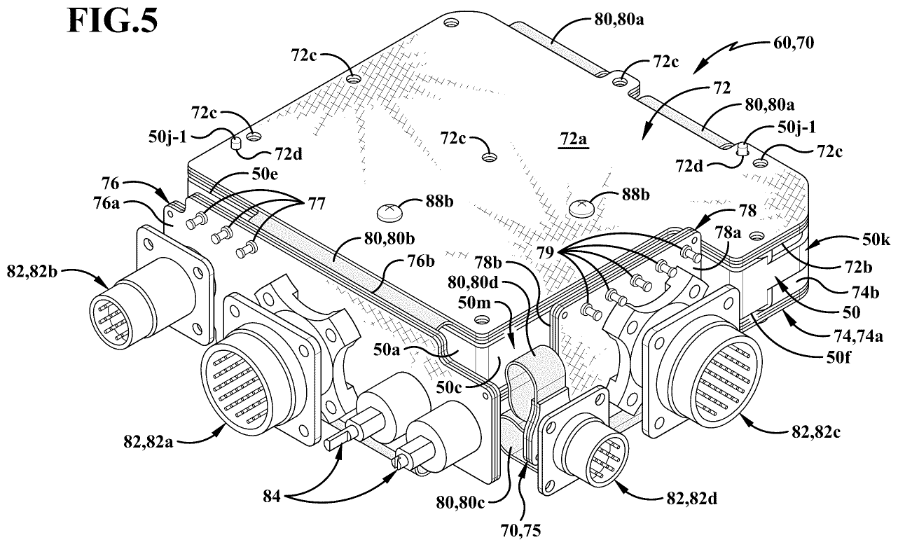

Control CCA 70 also includes a fourth circuit card 78 that operably engages with the chassis 20 at the first side wall 20c. In the present disclosure, fourth circuit card 78 includes an outer surface 78a that faces the first side wall 20c of chassis 20 when sequencer 10 is assembled, and an inner surface 78b that is opposite to the outer surface 78a and faces the first side wall 50c of internal support 50. As best seen in FIG. 9, the fourth circuit card 78 is positioned between the first side wall 20c of the chassis 20 and the first side wall 50c of the internal support 50. Additionally, fourth circuit card 78 is positioned inside of the compartment 50m of internal support 50 that is defined between the first side wall 50c and the extension 50k. As such, fourth circuit card 78 nests inside of the internal support 50 when the sequencer 10 is assembled (see FIG. 5).

Fourth circuit card 78 also defines a set of attachment holes 78c that extends entirely through the fourth circuit card 78 between the outer surface 78a and the inner surface 78b. Upon assembly, each attachment hole of the set of attachment holes 78c is configured to receive and house a portion of a connector so that fourth circuit card 78 may be secured to a second pair of connectors of the control CCA 70 that engages the fourth circuit card 78 with the chassis 20; such second pair of connectors of the control CCA 70 are discussed in greater detail below.

Fourth circuit card 78 also includes a set of terminals 79. As diagrammatically shown in FIG. 11, the set of terminals 79 includes a first terminal 79a that is operable for chassis ground, a second terminal 79b that is operable for 28V return signals, a third terminal 79c that is operable for 28V logic out signals, a fourth terminal 79d that is operable for 28V squib out signals, and a fifth terminal 79e that is operable for 28V return signals. It is understood two wires of a wiring harness connects with the set of terminals 79 to connect the fourth circuit card 78 with the third circuit card 76 and a power board of a power circuit card assembly, which is discussed in greater in below.

Control CCA 70 may also include an ethernet circuit card or panel 75. As best seen in FIG. 11, ethernet circuit card 75 is configured to be operable with an ethernet connector of control CCA 70 for signals that may be transmitted to the sequencer 10 and/or be transmitted from the sequencer 10. As discussed in greater detail below, the ethernet circuit card 75 is also operable with the fourth circuit card based on flexible connections of control CCA 70.

Control CCA 70 also includes flexible connections 80. As best seen in FIGS. 4A-4B, flexible connections 80 interconnect the first circuit card 72, the second circuit card 74, the third circuit card 76, and the fourth circuit card 78 with one another. Particularly, a first flexible connection 80a interconnects the first circuit card 72 and the second circuit card 74 with one another such that the first circuit card 72 and the second circuit card 74 may be operable with one another during operation. Additionally, a second flexible connection 80b interconnects the first circuit card 72 and the third circuit card 76 with one another such that the first circuit card 72 and the third circuit card 76 may be operable with one another during operation. Further, a third flexible connection 80c interconnects the second circuit card 74 and the fourth circuit card 78 with one another such that the second circuit card 74 and the fourth circuit card 78 may be operable with one another during operation. Lastly, a fourth flexible connection 80d interconnects the fourth circuit card 78 and the ethernet circuit card 75 (includes an ethernet connector of the control CCA 70) with one another such that the fourth circuit card 78 and the ethernet circuit card 75 may be operable with one another during operation; such description of the ethernet connector is discussed in greater detail below.

Control CCA 70 also includes a set of connectors 82. As best seen in FIGS. 4A-4B and 5, the set of connectors 82 includes a first connector 82a that operably engages with the third control board 76. It should be noted that the first connector 82a also operably engages the third control board 76 with the front wall 20a of chassis 20 at first opening 20j to secure the third control board 76 with the chassis 20. The set of connectors 82 also includes a second connector 82b that operably engages with the third control board 76. Similar to the first connector 82a, it should be noted that the second connector 82b operably engages the third control board 76 with the front wall 20a of chassis 20 at second opening 20k to secure the third control board 76 with the chassis 20. It should be noted that the first connector 82a and the second connector 82b form a first pair of connectors of the set of connectors 82 that is operable with the third circuit card 76 and operably engages the third circuit card 76 with the chassis 20.

In operation, first connector 82a is used to transmit communication to and from the control CCA 70 for various types of data in CMDS 6, including data relating to first set of fire lines of a first breechplate, data relating to magazine identification of a first magazine, chassis ground power return, data relating to discrete inputs and outputs, data relating to a sequencer data link (SDL), and data relating to dispenser data link (DDL) (e.g., power signals and RS-485 signals). In operation, second connector 82b is also used to transmit communication to and from the control CCA 70 for various types of data in CMDS 6, including 28V logic signals, data relating to discrete inputs and outputs, and data relating to the SDL interface.

Still referring FIGS. 4A-4B and 5, the set of connectors 82 also includes a third connector 82c that operably engages with the fourth control board 78. It should be noted that the third connector 82c also operably engages the fourth control board 78 with the first side wall 20c of chassis 20 at third opening 20n to secure the fourth control board 78 with the chassis 20. The set of connectors 82 includes a fourth connector 82d that operably engages with the ethernet control board 75. Similar to the third connector 82c, it should be noted that the fourth connector 82d also operably engages the ethernet control board 75with the first side wall 20c of chassis 20 at fourth opening 20p to secure the fourth control board 76 with the chassis 20. It should be noted that the third connector 82c and the fourth connector 82d form a second pair of connectors of the set of connectors 82 that is operable with the fourth circuit card 78 and the ethernet control board 75 and operably engages the fourth circuit card 78 with the chassis 20.

In operation, third connector 82c is used to transmit communication to and from the control CCA 70 for various types of data in CMDS 6, including data relating to a second set of fire lines of a second breechplate, data relating to magazine identification of a second magazine, chassis ground power return, data relating to discrete inputs and outputs, data relating to a sequencer data link (SDL), and data relating to dispenser data link (DDL) (e.g., power signals and RS-485 signals). In operation, fourth connector 82d is also used to transmit communication to and from the control CCA 70 for various types of data in CMDS 6, including ethernet capability. As such, fourth connector 82d may also be referred to as ethernet connector given such ethernet capabilities provided in sequencer 10. With such capability, control CCA 70 may be capable of transmitting data and/or information with on-board device or external device that also use or capable of transmitting data via ethernet.

In the present disclosure, one or more caps 83a may be engaged with one or more connectors of the set of connectors 82 prior to sequencer 10 being in use. As best seen in FIG. 2, caps 83a may be installed with the second connector 82b and the fourth connector 82d of the set of connectors 82 to protect the electrical connects housed inside of the respective connectors 82b, 82d. Additionally, lanyards 83b may also be engaged with the chassis 20 and a respective cap 83a to prevent the cap 83a from being separated from the sequencer 10 when the second connector 82b and the fourth connector 82d of the set of connectors 82 are in use.

Control CCA 70 also includes a pair of control switches 84. As best seen in FIGS. 4B and 5, the pair of control switches 84 is operably engaged with the third control board 76 adjacent to the first connector 82a. The pair of control switches 84 also extends through chassis 20 at the pair of recessed apertures 20m. In operation, the pair of control switches 84 is used to select a desired mode and address for sequencer 10; such modes and/or addresses are preconfigured with sequencer 10, particularly the control CCA 70, so that operators of sequencer 10 may quickly select such modes for a given military operation.

Control CCA 70 may also include a set of gaskets 86 that operably engage with the set of connectors 82. As best seen in FIGS. 10A-10B, a gasket of the set of gaskets 86 is placed between the chassis 20 and a clinch nut of a respective connector of the set of connectors 82. In one exemplary embodiment, each gasket of the set of gaskets 86 may be a spira gasket that is placed between the chassis 20 and the respective connector of the set of connectors 82. In the present disclosure, the set of gaskets 86 may be used as electromagnetic interference (EMI) shielding components to prevent electromagnetic disturbance or interference between the chassis 20 and the set of connectors 82 when sequencer 10 is operating.

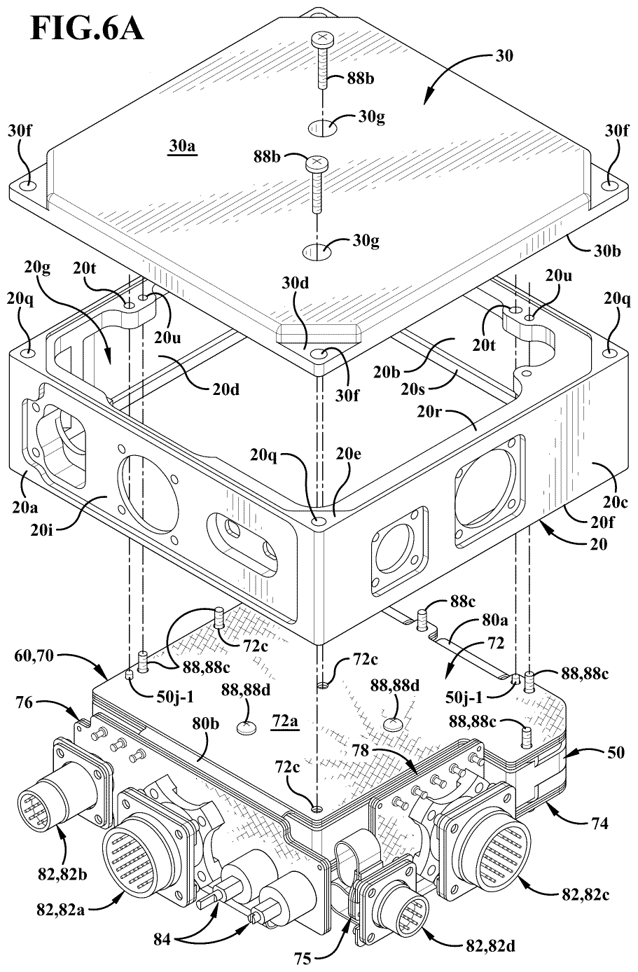

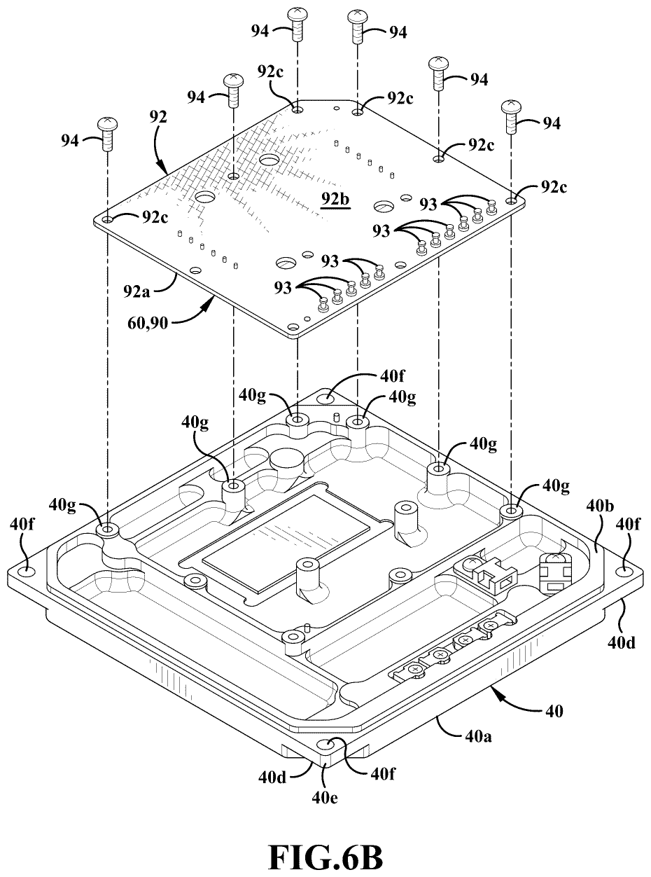

Control CCA 70 also includes a set of fasteners 88 that operably engages the components of control CCA 70 with the chassis 20, the top cover 30, the bottom cover 40, and/or the internal support 50. As best seen in FIG. 2, a first group of fasteners 88a of the set of fasteners 88 directly engages the set of connectors 82 with the chassis 20; such engagement provided by the first group of fasteners 88a also operably engages the third circuit card 76 and the fourth circuit card 78 with the chassis 20. As best seen in FIGS. 6A and 9, a second group of fasteners 88b of the set of fasteners 88 directly engages the set of standoffs 30g of the top cover 30, the first and set of standoffs 50i-1 of the internal support 50, and the first circuit card 72 among one another. As best seen in FIG. 8, a third group of fasteners 88c of the set of fasteners 88 directly engages the upper attachment flange 20r of chassis 20, the first and second sets of standoffs 50i-1, 50i-2 of internal support 50, first circuit card 72, and the second circuit card 74 together. As best seen in FIG. 9, a fourth group of fasteners 88d of the set of fasteners 88 directly engages the first set of standoffs 50i-1 of internal support 50 and the first circuit card 72 together and the second set of standoffs 50i-2 of internal support 50 and the second circuit card 74 together.

CCS 60 also includes a power circuit card assembly (hereinafter “power CCA”) that is generally referred to as 90 in FIG. 3D. Power CCA 90 includes a power board 92 that operably engages with the bottom cover 40 (See FIG. 6B). In the present disclosure, power board 92 includes an outer surface 92a that is spaced apart from the bottom cover 40 when sequencer 10 is assembled, and an inner surface 92b that is opposite to the outer surface 92a and operably engages with the set of standoffs 40g of bottom cover 40.

Power board 92 also includes a set of terminals 93. As diagrammatically shown in FIG. 11, the set of terminals 93 includes a first terminal 93a that is operable for 28V logic hold signals, a second terminal 93b that is operable for ground, a third terminal 93c that is operable for 28V logic out signals, a fourth terminal 93d that is operable for 28V squib out signals, a fifth terminal 93e that is operable for ground, and a sixth terminal 93f that is operable for chassis ground; this group of terminals is used to connect a wire of a wiring harness between the power board 92 and devices downstream or upstream to the sequencer 10 (e.g., one or more dispensers of CMDS 6), which is discussed in greater detail below. The set of terminal 93 further includes a seventh terminal 93g that is operable for chassis ground, an eighth terminal 93h that is operable for 28V return signals, a ninth terminal 93i that is operable for 28V squib in signals, a tenth terminal 93j that is operable for 28V logic in signals, and an eleventh signal that is operable for 28V return signals; this group of terminals is used to connect another wire of a wiring harness between the fourth circuit card 78 and the power board 92.

In the present disclosure, a set of fasteners 94 may be used to operably engage the power board 92 with the bottom cover 40. As best seen in FIG. 6B, each fastener of the set of fasteners 94 passes through a securement opening of the set of securement openings 92c of power board 92 and attaches with corresponding standoff of the set of standoffs 40g of bottom cover 40 that is aligned with said securement opening.

CCS 60 also includes a wiring harness 100 that interconnects the control CCA 70 and the power CCA 90 with one another. Specifically, wiring harness 100 interconnects the third control board 76, the fourth control board 78, and the power board 92 together to enable communication and transmission of signals between the control CCA 70 and the power CCA 90. Such wiring and/or electrical connection of wiring harness 100 are now discussed in greater detail below.

In the present disclosure, wiring harness 100 includes a first wire 102 that interconnects the third circuit card 76 and the fourth circuit card 78 together. As best seen in FIG. 11, first wire 102 includes a first electrical connection 102a that connects with first terminal 77a of third circuit card 76 and with the third terminal 79c of fourth circuit card 78; such first electrical connection 102a is used for 28V logic out signals. Still referring to FIG. 11, first wire 102 also includes a second electrical connection 102b that connects with second terminal 77b of third circuit card 76 and with second terminal 79b of fourth circuit card 78; such second electrical connection 102b is used for 28V return signals. Still referring to FIG. 11, first wire 102 also includes a third electrical connection 102c that connects with third terminal 77c of third circuit card 76 and with first terminal 79a of fourth circuit card 78; such third electrical connection 102c is used for chassis ground.

Wiring harness 100 also includes a second wire 104 that interconnects the fourth control board 78 and the power board 92 together. As best seen in FIG. 11, second wire 104 includes a first electrical connection 104a that connects with the seventh terminal 93g of power board 92 and with the first terminal 79a of fourth circuit card 87; such first electrical connection 104a is used for chassis ground. Second wire 104 also includes a second electrical connection 104b that connects with the eighth terminal 93h of power board 92 and with the fifth terminal 79e of fourth circuit card 78; such second electrical connection 104b is used for 28V return signals. Second wire 104 also includes a third electrical connection 104c that connects with the ninth terminal 93i of power board 92 and with the fourth terminal 79d of fourth circuit card 78; such third electrical connection 104c is used for 28V squib signals. Second wire 104 also includes a fourth electrical connection 104d that connects with the tenth terminal 93j of power board 92 and with the third terminal 79c of fourth circuit card 78; such fourth electrical connection 104d is used for 28V logic signals. Second wire 104 also includes a fifth electrical connection 104e that connects with the eleventh terminal 93k of power board 92 and with the second terminal 79b of fourth circuit card 78; such fifth electrical connection 104e is used for 28V return signals.

Wiring harness 100 also includes a third wire 106 that connects the fourth control board 78 and one of the first circuit card 72 and the second circuit card 74. As best seen in FIG. 11, third wire 106 includes a first electrical connection 106a that connects with the first terminal 93a of power board 92 and with a first terminal of one of the first circuit card 72 and the second circuit card 74; such first electrical connection 106a is used for 28V logic hold signals. Third wire 106 also includes a second electrical connection 106b that connects with the second terminal 93b of power board 92 and with a second terminal of one of the first circuit card 72 and the second circuit card 74; such second electrical connection 106b is used for ground. Third wire 106 also includes a third electrical connection 106c that connects with the third terminal 93c of power board 92 and with a third terminal of one of the first circuit card 72 and the second circuit card 74; such third electrical connection 106c is used for 28V logic signals. Third wire 106 also includes a fourth electrical connection 106d that connects with the fourth terminal 93d of power board 92 and with a fourth terminal of one of the first circuit card 72 and the second circuit card 74; such fourth electrical connection 106d is used for 28V squib signals. Third wire 106 also includes a fifth electrical connection 106e that connects with the fifth terminal 93e of power board 92 and with a fifth terminal of one of the first circuit card 72 and the second circuit card 74; such fifth electrical connection 106e is used for ground. Third wire 106 also includes a sixth electrical connection 106f that connects with the sixth terminal 93f of power board 92 and with a sixth terminal of one of the first circuit card 72 and the second circuit card 74; such sixth electrical connection 106f is used for chassis ground.

Having now discussed the components and elements of sequencer 10, a method of assembling sequencer 10 as shown in FIG. 2 is now discussed in greater detail below.

Initially, control CCA 70 may be introduced to internal support 50 to begin assembly of sequencer 10. In the present disclosure, the first circuit card 72 may be introduced to and engaged with the internal support 50 such that the inner surface 72b of first circuit card 72 rests on and is supported by the top end 50e of internal support 50. As the first circuit card 72 is being introduced to the internal support 50, the first set of alignment pins 50j-1 is passed through the first circuit card 72 at the first set of alignment apertures 72d so that the first circuit card 72 is aligned with the internal support 50 in the correct orientation (see FIG. 8). Once aligned, fasteners of the fourth group of fasteners 88d secures the first circuit card 72 to the internal support 50 at the first set of securement apertures 72c and at the first set of standoffs 50i-1 (see FIG. 9).

Subsequently, the second circuit card 74 may also be introduced to and engaged with the internal support 50 where the inner surface 74b of second circuit card 74 abuts the bottom end 50f of internal support 50. As the second circuit card 74 is being introduced to the internal support 50, the second set of alignment pins 50j-2 is passed through the second circuit card 74 at the second set of alignment apertures 74d so that the second circuit card 74 is aligned with the internal support 50 in the correct orientation (see FIG. 8). Once aligned, fasteners of the fourth group of fasteners 88d then secures the second circuit card 74 to the internal support 50 at the second set of securement apertures 74c and at the second set of standoffs 50i-2 (see FIG. 9).

Once the first circuit card 72 and second circuit card 74 are engaged with the internal support 50, the internal support 50, the first circuit card 72, and the second circuit card 74 may be collectively attached to the chassis 20. As best seen in FIG. 8, the third group of fasteners 88c pass through the internal support 50, the first circuit card 72, and the second circuit card 74 and engage with the chassis 20 at the upper attachment flange 20r. With such engagement, the internal support 50, the first circuit card 72, and the second circuit card 74 are collectively suspended from the chassis 20 via the third group of fasteners 88c inside of the chamber 20g.

Once the control CCA 70 is attached to the internal support 50, the third circuit card 76 and the fourth circuit card 78 may then be attached to the chassis 20. As best seen in FIG. 8, the third circuit card 76, the first connector 82a, the second connector 82b, and the pair of control switches 84 may be introduced to and engaged with the chassis 20, collectively, such that the first connector 82a and the second connector 82b are mounted to the front wall 20a of chassis 20. At this stage, the first group of fasteners 88a secures the first connector 82a and the second connector 82b with the front wall 20a of chassis 20 at the first opening 20j and at the second opening 20k. Once mounted, the third circuit card 76 is engaged with the chassis 20 and is positioned between the front wall 20a of chassis 20 and the front wall 50a of internal support 50. Subsequently, the fourth circuit card 78, the third connector 82c, and the fourth connector 82d may be introduced to and engaged with the chassis 20, collectively, such that the third connector 82c and the fourth connector 82d are mounted to the first side wall 20c of chassis 20. At this stage, the first group of fasteners 88a also secures the third connector 82c and the fourth connector 82d with the first side wall 20c of chassis 20 at the third opening 20n and at the fourth opening 20p. Once mounted, the fourth circuit card 78 is engaged with the chassis 20 and is positioned between the first side wall 20c of chassis 20 and the first side wall 50c of internal support 50 and inside of the compartment 50m defined by the internal support 50.

Separately, the power CCA 90 may be engaged with the bottom cover 40 of sequencer 10. As best seen in FIG. 8, the power board 92 is introduced to and engaged with the bottom cover 40 such that the outer surface 92a of power board 92 rests on and is supported by the inner surface 40b of bottom cover 40. Once the power board 92 is supported by the bottom cover 40, fasteners 94 are introduced to secure the power board 92 to the bottom cover 40 at the set of securement openings 92c and at the set of standoffs 40g (see FIGS. 6B and 8).

Prior to engaging the bottom cover 40 and the power board 92 with the chassis 20, collectively, the wiring harness 100 may be connected to the control CCA 70 and the power CCA 90. Particularly, the first wire 102 is connected to the third circuit card 76 at terminals 77 and to the fourth circuit card 78 at terminals 79, the second wire 104 is connected to the fourth circuit card 78 at terminals 79 and to the power board 92 at terminals 93, and the third wire 106 is connected to the power board 92 at terminals 93 and to one or both of the first circuit card 72 and the second circuit card 74 of control CCA 70. The wiring harness 100 is housed inside of and protected by chassis 20 from the external elements surrounding the chassis 20.

At this stage, the bottom cover 40 and the power CCA 90 may be introduced to and engaged with the chassis 20 such that the inner surface 40b of bottom cover 40 engages with the bottom end 20f of chassis 20 and the lower attachment flange 20s of chassis 20. Once the bottom cover 40 abuts the bottom end 20f of chassis 20 and the lower attachment flange 20s of chassis 20, the second set of fasteners 42 of bottom cover 40 secures the bottom cover 40 to the chassis 20 at the bottom end 20f of chassis 20 and at attachment openings 20q defined at the bottom end 20f of chassis 20.

Lastly, the top cover 30 may operably engage with the chassis 20, the internal support 50, and the control CCA 70 to complete the assembly of the sequencer 10. As best seen in FIG. 8, the inner surface 30b of top cover 30 rests on and is supported by the top end 20e of chassis 20 and by the upper attachment flange 20r of chassis 20. Once supported, the first set of fasteners 32 may be passed through the top cover 30 at the securement apertures 30f and threadably engaged with the attachment openings 20q defined at the top end 20e of chassis 20. Additionally, the first set of fasteners 32 may be passed through the top cover 30 at the set of securement apertures 30f and threadably engaged with the internal support 50 at a pair of standoffs of the first set of standoffs 50i-1 (see FIG. 9).

At this stage, the sequencer 10 is completely assembled such that the CCS 60 is fully housed and protected by the chassis 20, the top cover 30, and the bottom cover (see FIGS. 8-9). It should be noted that that the control CCA 70 is positioned vertically above the power CCA 90 when viewed from a longitudinal or transverse sectional view (see FIGS. 8-9).

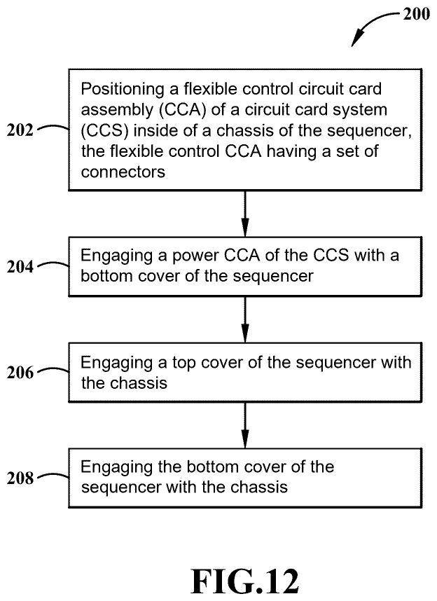

FIG. 12 illustrates a method 200 for assembling a sequencer. An initial step 202 of method 200 includes positioning a flexible control circuit card assembly (CCA) of a circuit card system (CCS) inside of a chassis of the sequencer, the flexible control CCA having a set of connectors; wherein one connector of the set of connectors is an ethernet connector. Another step 204 of method 200 includes engaging a power CCA of the CCS with a bottom cover of the sequencer. Another step 206 of method 200 includes engaging a top cover of the sequencer with the chassis. Another step 208 of method 200 includes engaging the bottom cover of the sequencer with the chassis.

In other exemplary embodiments, one or more optional or additional steps may be included with method 200 for assembling a sequencer. In one exemplary embodiment, method 200 may further include steps of engaging a first circuit card of the flexible control CCA with an internal support of the sequencer at a first surface of the internal support; and engaging a second circuit card of the flexible control CCA with the internal support of the sequencer at a second surface of the internal support opposite to the first surface. In another exemplary embodiment, method 200 may further include steps of engaging a third circuit card of the flexible control CCA with the chassis at a first position and is operable with a first pair of connectors of the set of connectors; and engaging a fourth circuit card of the flexible control CCA with the chassis at a second position orthogonal to the first position of the third circuit card and is operable with a second pair of connectors of the set of connectors; wherein the ethernet connector is included in the second pair of connectors. In another exemplary embodiment, method 200 may further include steps of engaging a set of flex connections with the first circuit card, the second circuit card, the third circuit card, and the fourth circuit card; wherein the set of flex connections interconnects the first circuit card, the second circuit card, the third circuit card, and the fourth circuit card with one another. In another exemplary embodiment, method 200 may further include a step of engaging the top plate with the internal support and the flexible control CCA by a set of connectors.

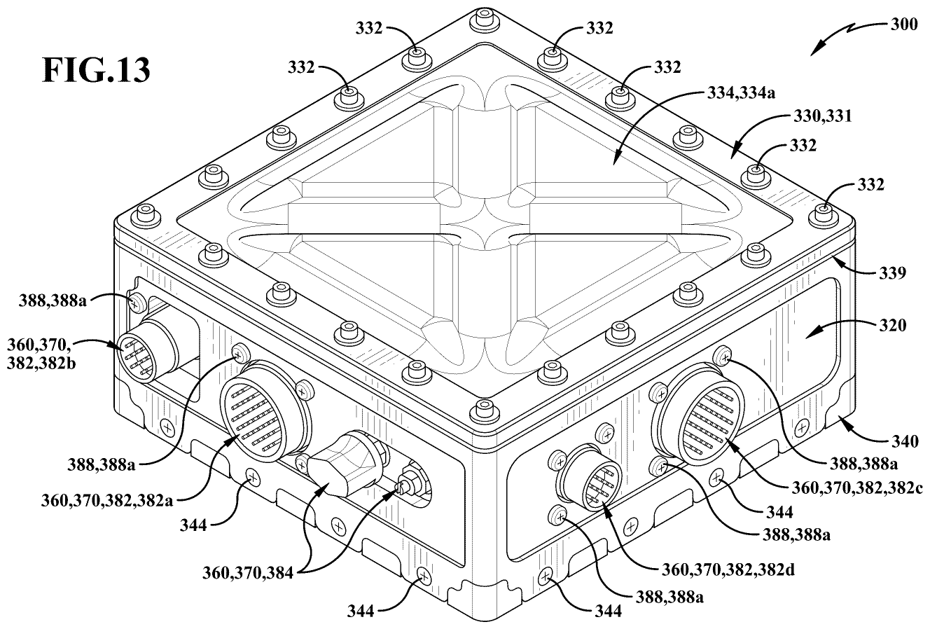

FIGS. 13-21 illustrate another sequencer 300. It should be understood that sequencer 300 is similar to sequencer 10 described above and illustrated in FIGS. 2-11.

Sequencer 310 includes a chassis 320 that is similar to chassis 20 of sequencer 10 discussed above. Particularly, chassis 320 includes a front wall 320a, a rear wall 320b, a first side wall 320c, a second side wall 320d, a top end 320e, a bottom end 320f, a chamber 320g, a first side recess 320h-1, a first base wall 320i-1 a first opening 320j, a second opening 320k, a pair of recessed apertures 320m, a third opening 320n, a fourth opening 320p, pairs of attachment openings 320q, and upper attachment flange 320r that are substantially similar to front wall 20a, rear wall 20b, first side wall 20c, second side wall 20d, top end 20e, bottom end 20f, chamber 20g, front recess 20h, base wall 320i-1, first opening 20j, second opening 20k, pair of recessed apertures 20m, third opening 20n, fourth opening 20p, pairs of attachment openings 20q, and upper attachment flange 20r of chassis 20. However, in this embodiment, chassis 320 includes some differences as compared to chassis 20 discussed previously which are now discussed in greater detail below.

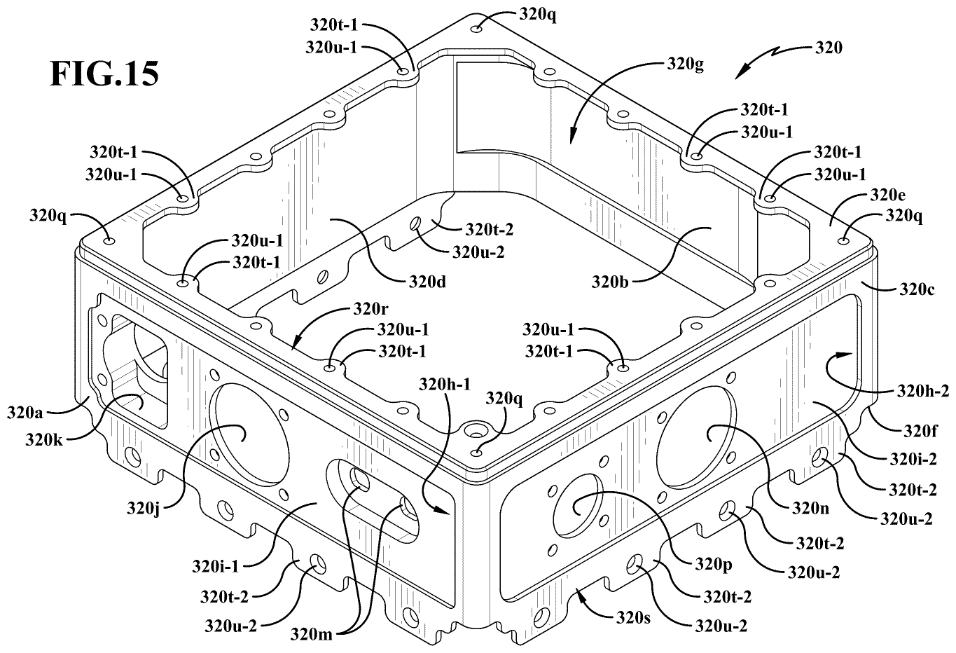

As best seen in FIG. 15, chassis 320 include a side recess 320h-2 that extends into the chassis 320 from the first side wall 320c to a second base wall 320i-2. Inside of the side recess 320h-2, the third opening 320n and fourth opening 320p are each defined in the second base wall 320i-2 of first side wall 320c in which the third opening 320n and fourth opening 320p are adjacent to one another along an axis that is parallel to the second axis of chassis 320.

Still referring to FIG. 15, chassis 320 includes a lower attachment flange 320s that extends downwardly from the front wall 320a, the rear wall 320b, the first side wall 320c, and the second side wall 320d and away from the chamber 320g. In the present embodiment, the lower attachment flange 320s is still located at the bottom end 20f of chassis 20 and is vertically opposite to the upper attachment flange 320r. Upper attachment flange 320r and lower attachment flange 320s also include a set of extensions where a first set of extensions 320t-1 is positioned along the perimeter of upper attachment flange 320r and a second set of extensions 320t-2 is positioned along the perimeter of lower attachment flange 320s. In this embodiment, however, the first set of extensions 320t-1 extends into the chamber 320g while the second set of extensions 320t-1 extends away from the chamber 320g and downwardly from the lower attachment flange 320s. Further, the first set of extensions 320t-1 defines a first set of securement holes 320u-1 while the second set of extensions 320t-2 defines a second set of securement holes 320u-2. Upon assembly, each securement hole of the sets of securement holes 320u-1, 320u-2 is configured to receive a connector to either operably engage a top cover of the sequencer 300 with the upper attachment flange 320r and a bottom cover of the sequencer 300 with the lower attachment flange 320s, which are discussed in greater detail below.

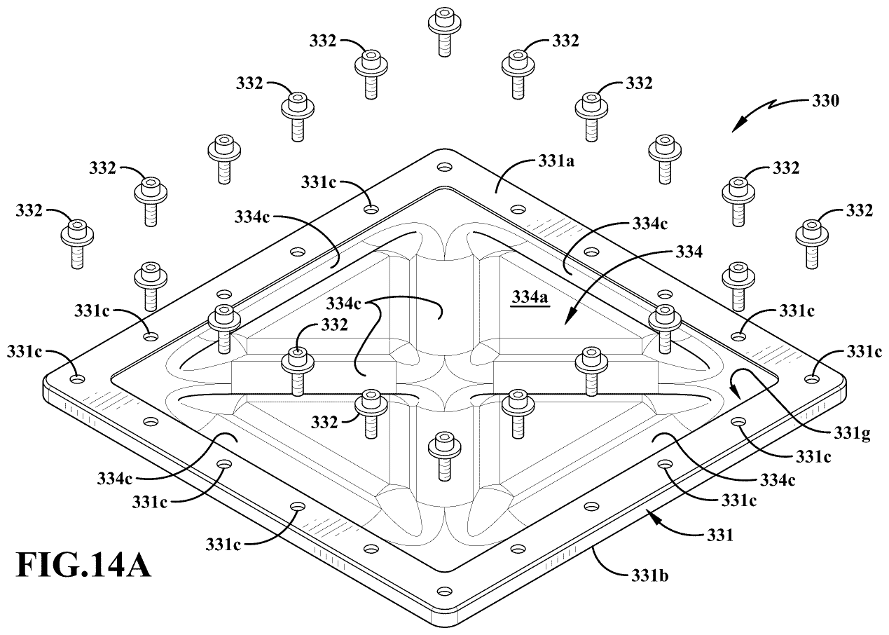

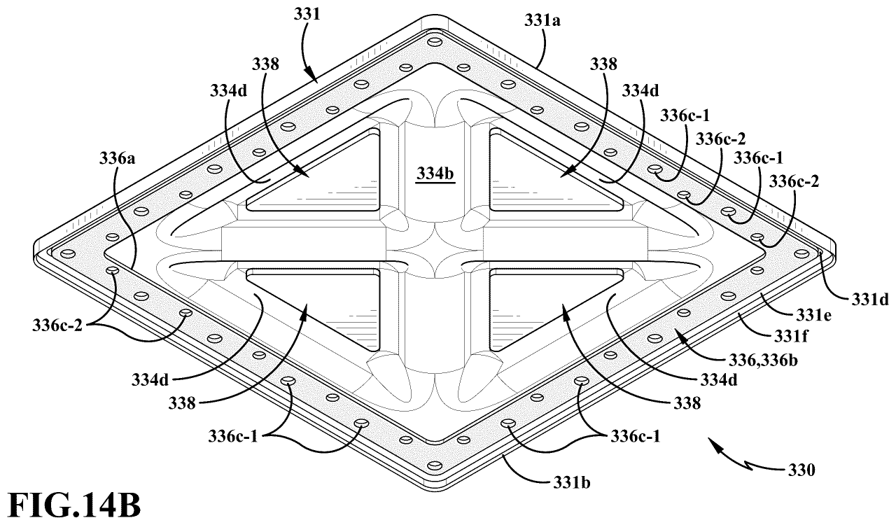

Sequencer 300 also includes a top cover 330 that removably engages with the chassis 320. As best seen in FIG. 14A, top cover 330 includes a frame 331 that includes an exterior or first end 331a that is free from contacting chassis 320, an interior or second end 331b opposite to the exterior end 331a and contacts the chassis 320, and a set of securement apertures 331c that extends through the frame 331 between the exterior end 331a and the interior end 331b. Referring to FIG. 14B, frame 311 also includes a first lateral surface 331d that extends upwardly from an internal base surface (not illustrated) of frame 331 to a first shoulder 331e that is substantially perpendicular to the first lateral surface 331d. Frame 311 also includes a second lateral surface 331f that extends upwardly from the first shoulder 331e to the interior end 331b. Such use of internal base surface, first lateral surface 331d, first shoulder 331e, and second lateral surface 331f are discussed in greater detail below.

Additionally, frame 331 is releasably engaged with the chassis 320, particularly the upper attachment flange 320r, with a set of fasteners 332. Particularly, the set of fasteners 332 pass through the set of securement apertures 331c and engages with the upper attachment flanges 320r inside of the securement holes 320u-1 to releasably engage the frame 331 with the chassis 320.

Still referring to top cover 330, top cover 330 also includes a plate 334 that operably engages with the frame 331. In the present disclosure, plate 334 includes an exterior surface 334a (see FIG. 14A) that faces the exterior environment surrounding the sequencer 300 and operably engages with the internal base surface and first lateral surface 331d of frame 331. Plate 334 also includes an interior surface 334b that is opposite to the exterior surface 334a and faces into the chassis 320 when assembled with chassis 320. In FIGS. 14A and 14B, plate 334 also defines a set of channels 334c that extends downwardly into the exterior surface 334a creating respective bulges or protrusions that extend outwardly from the interior surface 334b. Plate 334 also defines a set of internal recesses 334d that is collectively defined by the interior surface 334b and the protrusions created by the set of channels 334c in the exterior surface 334a; such use and purpose of the set of internal recesses 334d is discussed in greater detail below.

Still referring to top cover 330, top cover 330 also includes a gasket 336 that operably engages with the frame 331 and the plate 334. As best seen in FIG. 14B, gasket 336 includes a top engagement surface 336a that operably engages with the plate 334, a bottom engagement surface 336b that faces in an opposite direction relative to the top engagement surface 336b and operably engages with the chassis 320, particularly the upper flange attachment 320r, and a peripheral wall extending between the top and bottom engagement surfaces 336a, 336b that engages with the first lateral surface 331d of frame 331. The gasket 336 provides a seal between the chassis 320 and the top cover 330 for various reasons, including a seal to prevent fluid or unwanted debris into the chassis 320, prevention of unwanted movement or shock dampening that is experienced by the sequencer 300 during use in a platform, and other various reasons of the like. Gasket 336 also defines a first set of attachment apertures 336c-1 and a second set of attachment apertures 336c-2 that extend through gasket 336 between the top and bottom engagement surfaces 336a, 336b. In the present disclosure, the first set of attachment apertures 336c-1 allow the fasteners 332 to pass through so such fasteners 332 may releasably engage the chassis 320 and the top cover 330 with one another.

Still referring to top cover 330, top cover 330 also includes doublers 338 that are positioned inside of the internal recesses 334d defined in cover 330. In the present disclosure, doublers 338 are mounted in the recesses 334d of plate 334 of the top cover 330 to add damping to the top cover 330. With such dampening advantages by the doublers 338, the damping reduces response under vibration and acoustic noise environments and increases fatigue life of the top cover 330.

Upon engagement between the chassis 320 and the top cover 330, a torturous path 339 is defined between the top end 320e of chassis 320 and the interior end 331b of frame 331. Such inclusion of tortuous path 339 may eliminate inadvertent or unwanted contact between the chassis 320 and the top cover 330 when the sequencer 300 experiences outside forces that are transmitted from the platform during use.

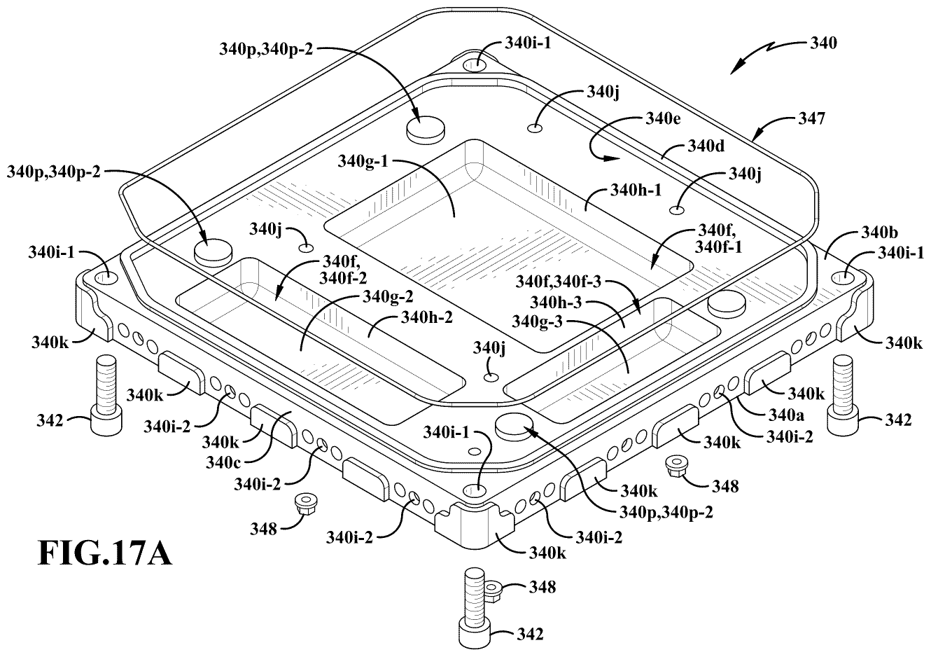

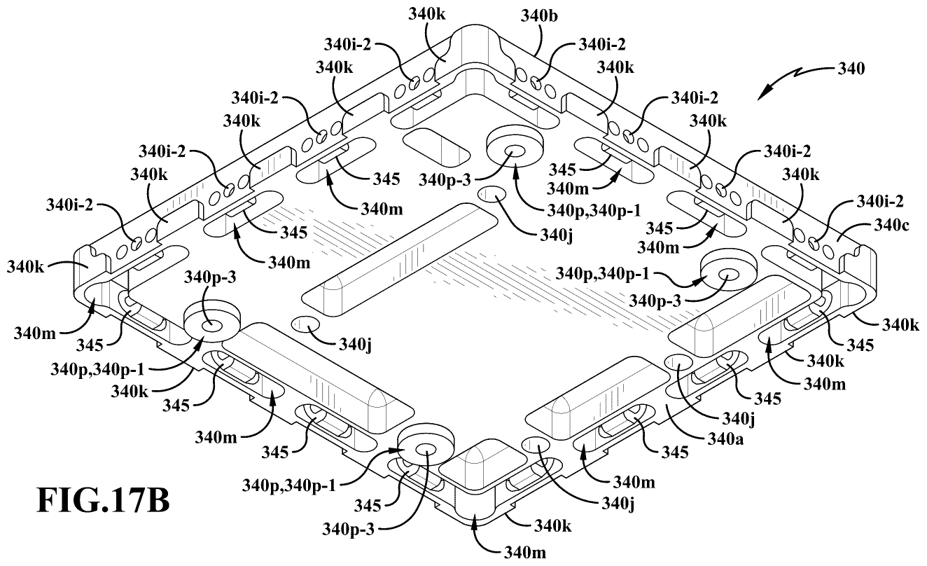

Sequencer 300 also includes a bottom cover 340 that removably engages with the chassis 320. As best seen in FIG. 17A, bottom cover 340 includes an exterior or first end 340a that faces into the exterior environment surrounding the sequencer 300, an interior or second end 340b that faces into the chassis 320 and operably engages with the chassis 320, particularly the lower attachment flange 320s, and a peripheral wall 340c extending between the exterior end 340a and the interior end 340b. Bottom cover 340 also includes a lip 340d that extends upwardly from the interior end 340b (see FIG. 17A); such use and purpose of lip 340d is discussed in greater detail below. Bottom cover 340 also includes a central recess 340e that is collectively defined by a portion of the interior end 340b (defined inside of the lip 340d) and the lip 340d.

Still referring to bottom cover 340, bottom cover 340 also defines a set of cavities. As best seen in FIG. 17A, a first cavity 340f-1 included in bottom cover 340 is collectively defined by a first base wall 340g-1 and a first lateral wall 340h-1 where the first cavity 340f-1 extends downwardly from the interior end 340b, along first lateral wall 340h-1, and terminates at the first base wall 340g-1. Similarly, a second cavity 340f-2 included in bottom cover 340 is collectively defined by a second base wall 340g-2 and a second lateral wall 340h-2 where the second cavity 340f-2 extends downwardly from the interior end 340b, along second lateral wall 340h-2, and terminates at second base wall 340g-2. Further, a third cavity 340f-3 included in bottom cover 340 is collectively defined by a third base wall 340g-3 and a third lateral wall 340h-3 where the third cavity 340f-3 extends downwardly from the interior end 340b, along third lateral wall 340h-3, and terminates at third base wall 340g-3. Such use and purposes of cavities 340f-1, 340f-2, 340f-3 are discussed in greater detail below.

Still referring to bottom cover 340, bottom cover 340 also defines sets of securements apertures. As best seen in FIG. 17A, bottom cover 340 defines a first set of securements apertures 340i-1 that extends through the bottom cover 340 from the exterior end 340a to the interior end 340b. It should be noted that the first set of securement apertures 340i-1 are positioned outside of the central recess 340e and spaced outward of the lip 340d. Bottom cover 340 also includes a second set of securement apertures 340i-2 where each securement aperture is defined in the peripheral wall 340c and is accessible from the exterior environment of the bottom cover 340 or an associated pocket defined in the bottom cover 340, which is discussed in greater detail below. Bottom cover 340 also defines a set of alignment through-holes 340j that extends through the bottom cover 340 from the exterior end 340a to the interior end 340b. It should be noted that such alignment through-holes 340j are positioned inside of the central recess 340e and spaced inward from the lip 340d. As discussed in greater detail below, the alignment through-holes 340j allow one or more alignment pins or members of circuit card system of sequencer 300 to align with the bottom cover 340 when the sequencer 300 is being assembled.

Still referring to bottom cover 340, bottom cover 340 includes engagement members 340k. As best seen in FIGS. 17A-17B, each engagement member 340k extends outwardly from the peripheral wall 340c and are equally distanced from one another on the peripheral wall 340c. It should be noted the engagement members 340k may define one or more two-dimensional shapes. In one example, a first group of engagement members 340k defines a substantially rectangular or symmetric two-dimensional shape when viewed from a front isometric view (see FIG. 17A). In another example, a second group of engagement members 340k defines a polygonal or asymmetrical two-dimensional shape when viewed from a front isometric view (see FIG. 17A). Upon assembly, the set of engagement members 340k is configured to engage with the lower attachment flange 320s of chassis 320 such that the chassis 320 and the bottom cover 340 are interlocked with one another. Stated differently, the set of engagement members 340k is configured to operably mesh with the lower attachment flange 320s of chassis 320 such that the chassis 320 and the bottom cover 340 are interlocked with one another.

Still referring to bottom cover 340, bottom cover 340 also includes a set of pockets 340m. As best seen in FIG. 17B, each pocket 340m extends upwardly into the bottom cover 340 from the exterior end 340a and terminates at a base wall before reaching the interior surface 340b; as such, each pocket 340m is only accessible from the exterior end 340a of the bottom cover 340. Each pocket 340m is also in operative communication with a group of securement apertures of the second set of securement apertures 340i-2. In one example, each pocket 340m is also in operative communication with a group of three securement apertures of the second set of securement apertures 340i-2. As discussed in greater detail below, each pocket 340m provides access to housing a nut plate that releasably engages with a respective fasteners of bottom cover 340 to fixedly engage the chassis 320 and the bottom cover 340 with one another.

Still referring to bottom cover 340, bottom cover 340 also includes a set of feet 340p. In the present disclosure, each foot 340p includes an engagement end 340p-1 (see FIG. 17B) that extends outwardly from the exterior end 340a and is adapted to engage with a support surface or structure of a platform, a terminal end 340p-2 (see FIG. 17A) that extends outwardly from the interior end 340b, and a passageway 340p-3 that extends between the engagement end 340p-1 and the terminal end 340p-2. In one example, the passageway 340p-3 of each foot 340p may be threaded so that a fastener may be threadably engaged with each foot 340p to retain the bottom cover 340 (as well as the sequencer 300 as a whole) to support surface or structure of a platform.

Still referring to bottom cover 340, bottom cover 340 also includes sets of fasteners. As best seen in FIG. 17A, a first set of fasteners 342 is configured to pass through and engage with the bottom cover 340 at the first set of securement apertures 340i-1 and threadaby engage with the chassis 320 at threaded apertures (not illustrated) defined in the chassis. As best seen in FIG. 13, a second set of fasteners 344 is configured to pass through and engage with the lower attachment flange 320s the chassis 320 at securement holes 320u-2 and engage with the bottom cover 340 at securement holes 340i-2. Additionally, the second set of fasteners 344 releasably engages with a set of nut plates 345 where each nut plate 345 is housed inside of a respective pocket 340m defined in the bottom cover 340 and aligned with a respective securement hole 340i-2 to receive fastener 344. Such engagement between the second set of fasteners 344 and the set of nut plates 345 fixedly engages the chassis 320 and the bottom cover 340 with one another.

Still referring to bottom cover 340, bottom cover 340 also includes an O-ring 347 that operably engages with the lip 340d external to the central recess 340e. In operation, the O-ring 347 provides a seal between the bottom cover 340 and components of a circuit card system of sequencer 300 to prevent unwanted fluid or debris from entering into the central recess 340e where such components of the circuit card system are housed. Bottom cover 340 also includes a set of nuts 348 that releasably engage with connectors or bolts of a power circuit card assembly of sequencer 300 to fixedly engage the bottom cover 340 and components of the power circuit card assembly with one another; such components of the power circuit card assembly are discussed in greater detail below.

Sequencer 300 also includes a pair of internal supports 350A, 350B that operably engage with one another to support two or more circuit cards of a circuit card system of sequencer 300. In the present disclosure, the pair of internal supports 350A, 350B are identical to one another and are mirror images of one another. With such identical configurations, the first internal support 350A will be described in more detail below for brevity. It should be understood that while the first internal support 350A is discussed in greater detail below, the description of the first internal support 350A applies equally to the second internal support 350B.

In this embodiment, the first internal support 350A is substantially similar to internal support 50 of sequencer 10 discussed above. Particularly, first internal support 350A includes a front wall 350a, a rear wall 350b, a first side wall 350c, a second side wall 350d, an outer end 350e, an inner end 350f, a set of standoffs 350i, a set of alignment pins 350j, an extension 350k, and a compartment 350m collectively defined by the first side wall 350c and the extension 350k that are substantially similar to front wall 50a, rear wall 50b, first side wall 50c, second side wall 50d, top end 50e, bottom end 50f, set of standoffs 50i, set of alignment pins 50j, extension 50k, and compartment 50m collectively defined by first side wall 50c and extension 50k of internal support 50. However, in this embodiment, first internal support 350A includes some differences as compared to internal support 50 discussed previously which are now discussed in greater detail below.

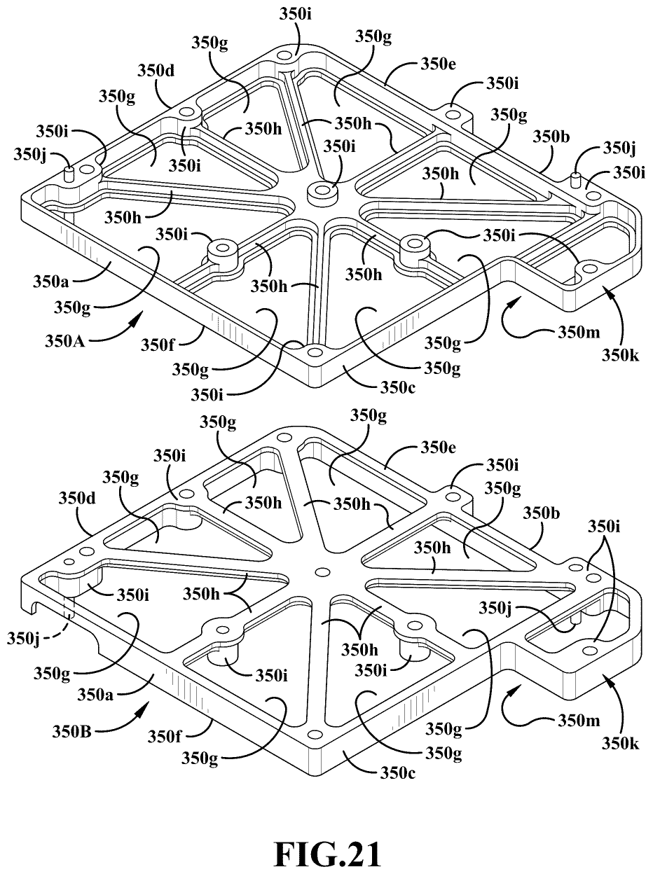

As best seen in FIG. 21, the first internal support 350A includes a set of openings 350g that is defined collectively by the outer end 350e, the inner end 350f, and at least two retaining walls of a set of retaining walls 350h. Such removal of material to define the set of openings 350g may reduce the overall weight of the first internal support 350A as well as the overall weight of the sequencer 300.

Sequencer 300 also includes a circuit cart system (CCS) 360 that is similar to CCS 60 of sequencer 10 discussed above. Such similarities between CCS 60 of sequencer 10 and CCS 360 of sequencer 300 are discussed in greater detail below.

In this embodiment, CCS 360 includes a control circuit card assembly (control CCA) 370 that is substantially similar to control CCA 70 of sequencer 10 discussed above. Particularly, control CCA 370 includes a first circuit card 372 that has an outer surface 372a, an inner surface 372b, and securement openings 372c that are substantially similar to outer surface 72a, inner surface 72b, and securement openings 72c of first circuit card 72 of control CCA 70. Similarly, control CCA 370 includes a second circuit card 374 that has an outer surface 374a, an inner surface 374b, and securement openings 374c that are substantially similar to outer surface 74a, inner surface 74b, and securement openings 74c of second circuit card 74 of control CCA 70; a third circuit card 376 that has an outer surface 376a, an inner surface 376b, securement openings 376c, and terminals 377 that are substantially similar to outer surface 76a, inner surface 76b, securement openings 76c, and terminals 77 of third circuit card 76 of control CCA 70; and a fourth circuit card 378 that has an outer surface 378a, an inner surface 378b, securement openings 378c, and terminals 379 that are substantially similar to outer surface 78a, inner surface 78b, securement openings 78c, and terminals 79 of fourth circuit card 78 of control CCA 70. It should also be understood that circuit cards 372, 374, 376, 378 of control CCA 370 operate substantially similar to circuit cards 72, 74, 76, 78 of control CCA 70.

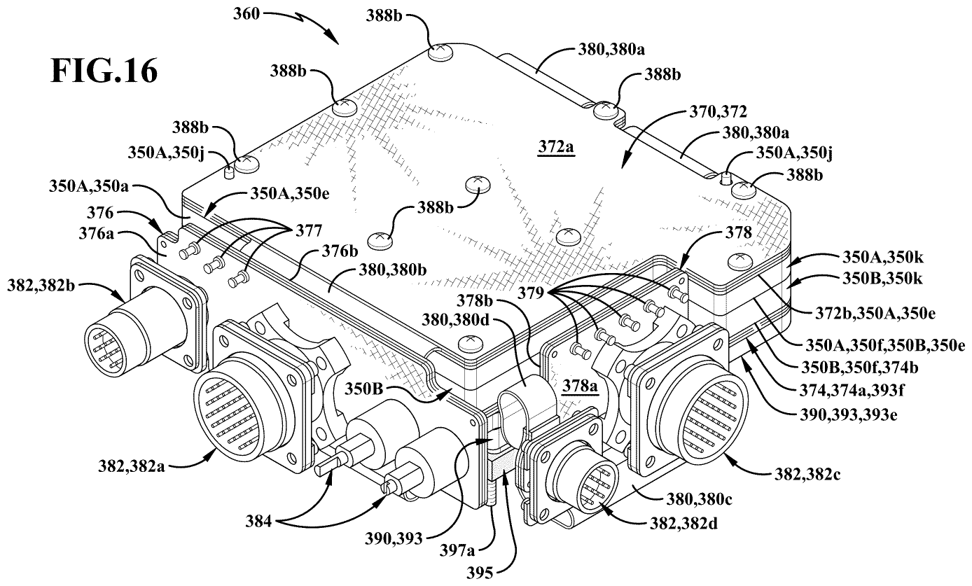

However, in this embodiment, the structural arrangement between the internal supports 350A, 350B and circuit cards 372, 374 of control CCA 370 are different from the structural arrangement between the internal support 50 and circuit cards 72, 74 of control CCA 70. As best seen in FIG. 16, the first circuit card 372 is configured to operably engage with and be supported by the first internal support 350A, and the second circuit card 374 is configured to operably engage with and be supported by the second internal support 350B.

In this embodiment, control CCA 370 includes additional components that are substantially similar to components of control CCA 70 of sequencer 10 discussed above. Particularly, control CCA 370 includes a set of connectors 382 that includes a first connector 382a, a second connector 382b, a third connector 382c, and a fourth connector 382d and a pair of control switches 384 that are substantially similar to first connector 82a, second connector 82b, third connector 82c, and fourth connector 82d of set of connectors 82 and pair of control switches 84 of control CCA 70. Control CCA 370 also includes fasteners 388 that make up a first group of fasteners 388a and a second group of fasteners 388b that are substantially similar to fasteners 88 that make up first group of fasteners 88a and second group of fasteners 88b of control CCA 70. While not illustrated herein, wires and/or electrical connections are provided with control CCA 370 to electrically connect the circuit cards 376, 378 (and attached connectors 382) with the circuit cards 372, 374 and other necessary electrical components as previously discussed in sequencer 10.

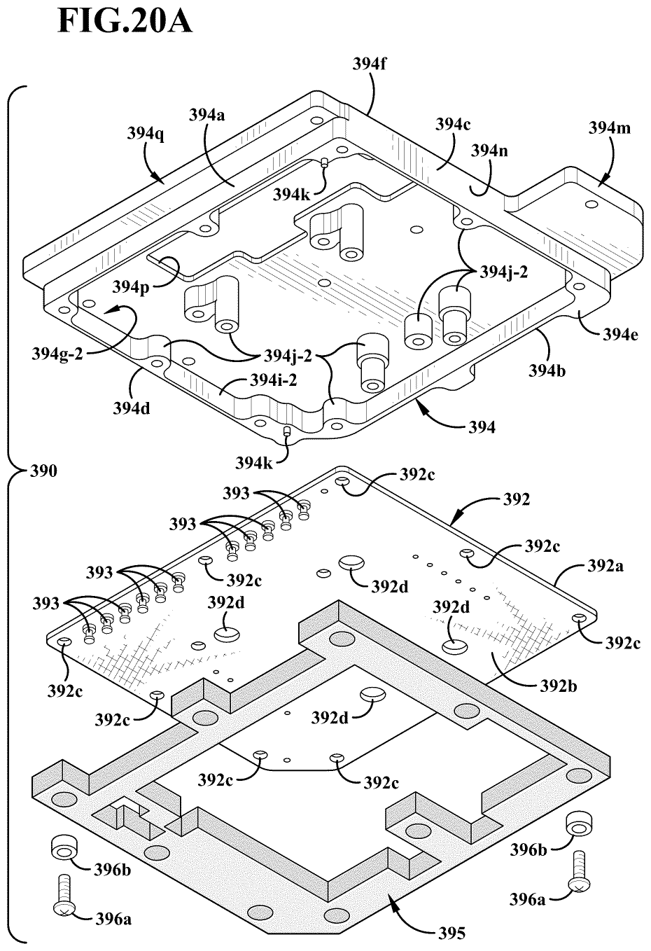

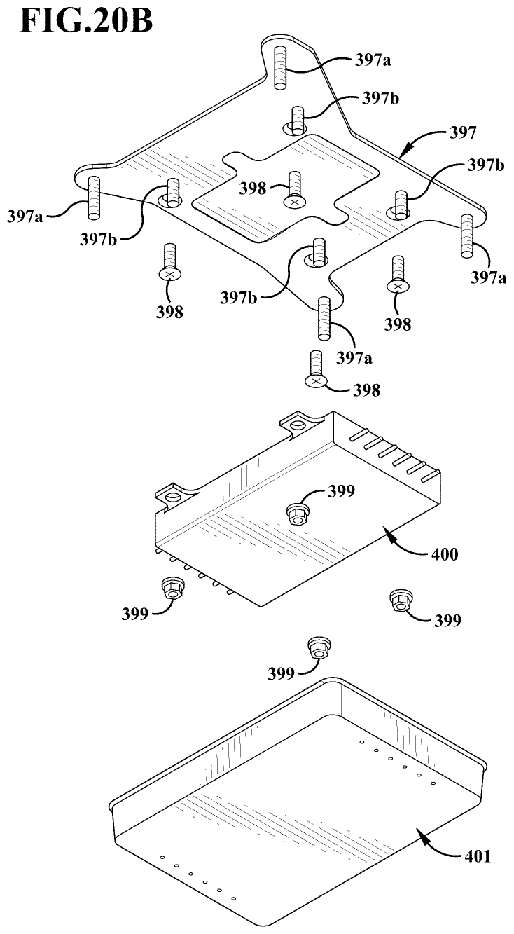

CCS 360 of sequencer 300 also includes a power circuit card assembly (power CCA) 390 that is substantially similar to power CCA 90 of sequencer 10 discussed above. Particularly, and as best seen in FIG. 20A, power CCA 390 includes a power board 392 that includes a top surface 392a, a bottom surface 392b, a set of securement openings 392c, a set of through-holes 392d, and a set of terminals 393 that are substantially similar to top surface 92a, bottom surface 92b, set of securement openings 92c, set of through-holes 92d, and set of terminals 93 of power board 92 of power CCA 90.

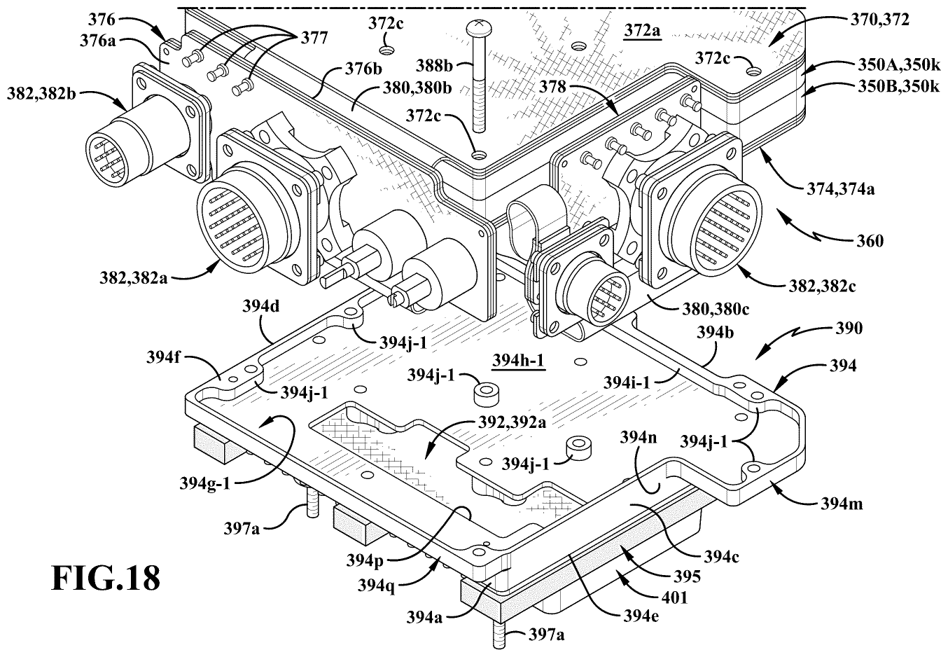

However, power CCA 390 includes additional components that are not included with power CCA 90 of sequencer 10. As best seen in FIGS. 18-20B, power CCA 390 includes a frame 394 that includes a first or front wall 394a, a second or rear wall 394b that is opposite to the front wall 394a, and a first axis defined between the front wall 394a and the second wall 394b. Frame 394 also includes a first side wall 394c, a second side wall 394d that is opposite to the first side wall 394c, and a second axis defined between the first side wall 394c and the second side wall 394d; the second axis is orthogonal to the first axis of the frame 394. Frame 394 also includes an outer end 394e that is collectively defined by the front wall 394a, the rear wall 394b, the first side wall 394c, and the second side wall 394d, an inner end 394f that is collectively defined by the front wall 394a, the rear wall 394b, the first side wall 394c, and the second side wall 394d and is opposite to the outer end 394e, and a third axis defined between the outer end 394e and the inner end 394f.

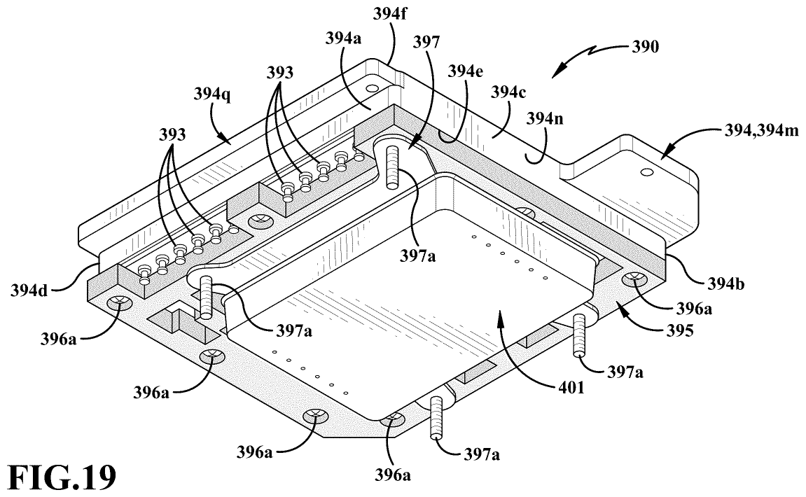

Still referring to frame 394, frame 394 also defines a pair of central recesses 394g-1, 394g-2. In FIG. 18, frame 394 defines a first central recess 394g-1 that extends downwardly into the frame 394 from the inner end 394f to a first base surface 394h-1 along a first internal lateral surface 394i-1. Such use of first central recess 394g-1 may allow for one or more components of the second circuit card 374 to be housed inside of the first central recess 394g-1 once sequencer 300 is assembled. In FIG. 20, frame 394 also defines a second central recess 394g-2 that extends upwardly into the frame 394 from the outer end 394e to a second base surface 394h-2 along a second internal lateral surface 394i-2. Such use of second central recess 394g-2 may allow for the power board 392 to be housed inside of the second central recess 394g-2 once sequencer 300 is assembled (see FIG. 19).

Still referring to frame 394, frame 394 also includes sets of standoffs or bosses. In FIG. 18, frame 394 includes a first set of standoffs 394j-1 that extends into the first central recess 394g-1 from one or more of the front wall 394a, rear wall 394b, first side wall 394c, and second side wall 394d. In FIG. 20, frame 394 also includes a second set of standoffs 394j-2 that extend outwardly from second base surface 394h-2 and away from the second central recess 394g-2. Upon assembly, each standoff of first set of standoffs 394j-1 is configured to receive and engage with a respective fasteners 388b for fixedly engaging the frame 394 with the internal supports 350A, 350B and the control CCA 370. Upon assembly, each standoff of second set of standoffs 394j-2 is configured to receive and engage with connectors 396a and inserts 396b that fixedly engage with the power board 392 and a pad 395 of power CCA 390. It should be noted that pad 395 may prevent and/or block potting material of sequencer 300 from entering under a power CCA of sequencer 300.

Still referring to frame 394, frame 394 also includes alignment pins 394k. As best seen in FIG. 20A, each alignment pin 394k extends outwardly from the outer end 394e. Upon assembly, each alignment pin 394k is configured to pass through and engage with power board 392 so that the power board 392 is substantially aligned with the frame 394.

Still referring to frame 394, frame 394 also includes an extension 394m. As best seen in FIG. 20A, extension 394m protrudes outwardly from the rear wall 394b and the first side wall 394c. It will be understood that extension 394m may further define and be an addition to the top end 394e for engaging one or more circuit cards of control CCA 370. Extension 394m also includes a standoff from the first set of standoffs 394i-1 for engaging one or more circuit cards of a control circuit card assembly of the sequencer 300. Additionally, a compartment 394n is defined collectively by the first side wall 394c and the extension 394m. Upon assembly of sequencer 300, a portion fourth circuit card 378 of the control CCA 370 is housed inside of the compartment 394n.

Still referring to frame 394, frame 394 defines a cutout 394p. As best seen in FIG. 20A, cutout 394p is collectively defined by first and second base surfaces 394h-1, 394h-2 to allow for clearance of one or more components or electrical connections of the control CCA 360 when the sequencer 300 is assembled. Additionally, frame 394 also includes a wing or shelf 394q that extends from front wall 394a. Wing 394q includes a standoff from the first set of standoffs 394i-1 for engaging one or more circuit cards of control CCA 360 and internal supports 350A, 350B.

Power CCA 390 also includes a module mounting plate 397 that fixedly engages a DC converter 400 with the frame 394 (see FIG. 19). The mounting plate 397 includes a first set of threaded shafts 397a that threadably engage with nuts 348 of bottom cover 340 to fixedly engage the mounting plate 397 with the bottom cover 340. Additionally, mounting plate 397 includes a second set of threaded shafts 397b that threadably engage with nuts 399 to fixedly engage the DC converter 400 with the mounting plate 397. Further, a set of fasteners 398 fixedly engages the module mounting plate 397 with the frame 394 at least one standoffs of the second set of standoffs 394i-2. Additionally, a thermal interface component 401 having thermal interface material surrounds the DC converter 400 to assist in dissipating heat through the bottom cover 340 and into the mounting surface of sequencer 300. Additionally, material dispensed inside of a cavity of the component 401 is a thick paste where the DC converter 400 is housed prior to installing the CCS 360.

Sequencer 300 (and other sequencers mentioned herein) may also be loaded with a potting material prior to the top cover 330 of sequencer 330 being installed. In the present disclosure, the potting material is injected into the space between the chassis 320 and CCS 360 to dampen the response of the circuit cards included in CCS 360, the chassis 320, and the connectors included in sequencer 300 from vibration environments that the sequencer 300 may be subjected to during military operations. With such damping capabilities, the potting material dissipates vibration energy inside of the sequencer 300, reduces mechanical stresses inside of the sequencer 300, decreases the likelihood of fatigue relates failures, and leads to longer service life when used in fielded aircraft and other military platforms of the like. In one exemplary embodiment, the potting material may be an elastomeric compound mixed with a catalyst and poured into a chamber collectively defined by the chassis 320 and the bottom cover 340 where the potting material fills in empty voids or spaces between the CCS 360 and the chassis 320 and the bottom cover 340 and cures inside such chamber.

As described herein, aspects of the present disclosure may include one or more electrical, pneumatic, hydraulic, or other similar secondary components and/or systems therein. The present disclosure is therefore contemplated and will be understood to include any necessary operational components thereof. For example, electrical components will be understood to include any suitable and necessary wiring, fuses, or the like for normal operation thereof. Similarly, any pneumatic systems provided may include any secondary or peripheral components such as air hoses, compressors, valves, meters, or the like. It will be further understood that any connections between various components not explicitly described herein may be made through any suitable means including mechanical fasteners, or more permanent attachment means, such as welding or the like. Alternatively, where feasible and/or desirable, various components of the present disclosure may be integrally formed as a single unit.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Any flowchart and/or block diagrams in the Figures illustrate some exemplary architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc. As another example, “at least one of: A, B, or B” is intended to cover A, B, C, A-B, A-C, B-C, and A-B-C, as well as any combination with multiple of the same item.

While components of the present disclosure are described herein in relation to each other, it is possible for one of the components disclosed herein to include inventive subject matter, if claimed alone or used alone. In keeping with the above example, if the disclosed embodiments teach the features of components A and B, then there may be inventive subject matter in the combination of A and B, A alone, or B alone, unless otherwise stated herein.

As used herein in the specification and in the claims, the term “effecting” or a phrase or claim element beginning with the term “effecting” should be understood to mean to cause something to happen or to bring something about. For example, effecting an event to occur may be caused by actions of a first party even though a second party actually performed the event or had the event occur to the second party. Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

To the extent that the present disclosure has utilized the term “invention” in various titles or sections of this specification, this term was included as required by the formatting requirements of word document submissions pursuant the guidelines/requirements of the United States Patent and Trademark Office and shall not, in any manner, be considered a disavowal of any subject matter.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

What is claimed is:

1. A sequencer for a countermeasure dispensing system, comprising:
a chassis;
a top cover operably engaged with the chassis at a first position;
a bottom cover operably engaged with the chassis at a second position;
a chamber defined by the chassis; and
a circuit card system (CCS) operably engaged with the chassis, the top cover, and the bottom cover and substantially housed inside of the chamber and having a set of connectors; wherein one connector of the set of connectors is an ethernet connector.

2. The sequencer of claim 1, further comprising:
an internal support housed inside of the chamber and supporting the CCS.

3. The sequencer of claim 2, wherein the CCS further comprises:
a flexible control circuit card assembly (CCA) operably engaged with the chassis and the internal support.

4. The sequencer of claim 3, wherein the flexible control CCA comprises:
a first circuit card operably engaged with the internal support at a first surface; and
a second circuit card operatively engaged with the internal support at a second surface opposite to the first surface.

5. The sequencer of claim 4, wherein the flexible control CCA further comprises:
a third circuit card operably engaged with the chassis at a first location and is operable with a first pair of connectors of the set of connectors; and
a fourth circuit card operably engaged with the chassis at a second location spaced apart from the first position of the third circuit card and is operable with a second pair of connectors of the set of connectors;
wherein the ethernet connector is included in the second pair of connectors.

6. The sequencer of claim 5, wherein the first circuit card and the second circuit card are parallel to one another on the internal support; and
wherein the third circuit card and the fourth circuit card are orthogonal to one another.

7. The sequencer of claim 5, wherein the control CCA further comprises:
a set of flex connections operably engaging with the first circuit card, the second circuit card, the third circuit card, and the fourth circuit card;
wherein the set of flex connections interconnects the first circuit card, the second circuit card, the third circuit card, and the fourth circuit card with one another.

8. The sequencer of claim 4, further comprising:
a set of alignment pins operably engaged with at least the internal support; and
a set of alignment members formed in the chassis;
wherein the set of alignment pins are configured to engage with the alignment members to align the internal support with the chassis.

9. The sequencer of claim 8, wherein the set of alignment pins are configured to engage with the first circuit card and the second circuit card to align the first circuit card and the second circuit card with the internal support.

10. The sequencer of claim 3, further comprising:
a power CCA operably engaged with the bottom cover and spaced apart from the internal support;
wherein the power CCA and the flexible control CCA are operable with one another.

11. The sequencer of claim 1, wherein the ethernet connector is configured to output a broadband signal up to approximately one gigabit per second.

12. A circuit card system (CCA) of a sequencer, comprising:
an internal support housed inside of a chamber defined by the sequencer;
a flexible control circuit card assembly (CCA) operably engaged with a chassis of the sequencer and the internal support;
a power CCA operably engaged with a bottom cover of the sequencer and spaced apart from the internal support; and
a set of connectors of the flexible control CCA; wherein one connector of the set of connectors is an ethernet connector;
wherein the power CCA and the flexible control CCA are operable with one another.

13. The sequencer of claim 12, wherein the flexible control CCA comprises:
a first circuit card operably engaged with the internal support at a first surface; and
a second circuit card operatively engaged with the internal support at a second surface opposite to the first surface.

14. The sequencer of claim 13, wherein the flexible control CCA comprises:
a third circuit card operably engaged with the chassis at a first position and is operable with a first pair of connectors of the set of connectors; and
a fourth circuit card operably engaged with the chassis at a second position orthogonal to the first position of the third circuit card and is operable with a second pair of connectors of the set of connectors;
wherein the ethernet connector is included in the second pair of connectors.

15. The sequencer of claim 14, wherein the control CCA further comprises:
a set of flex connections operably engaging with the first circuit card, the second circuit card, the third circuit card, and the fourth circuit card;
wherein the set of flex connections interconnects the first circuit card, the second circuit card, the third circuit card, and the fourth circuit card with one another.

16. A method of assembling a sequencer, comprising:
positioning a flexible control circuit card assembly (CCA) of a circuit card system (CCS) inside of a chassis of the sequencer, the flexible control CCA having a set of connectors; wherein one connector of the set of connectors is an ethernet connector;
engaging a power CCA of the CCS with a bottom cover of the sequencer;
engaging a top cover of the sequencer with the chassis; and
engaging the bottom cover of the sequencer with the chassis.

17. The method of claim 16, further comprising:
engaging a first circuit card of the flexible control CCA with an internal support of the sequencer at a first surface of the internal support; and
engaging a second circuit card of the flexible control CCA with the internal support of the sequencer at a second surface of the internal support opposite to the first surface.

18. The method of claim 17, further comprising:
engaging a third circuit card of the flexible control CCA with the chassis at a first position and is operable with a first pair of connectors of the set of connectors; and
engaging a fourth circuit card of the flexible control CCA with the chassis at a second position orthogonal to the first position of the third circuit card and is operable with a second pair of connectors of the set of connectors;
wherein the ethernet connector is included in the second pair of connectors.

19. The method of claim 18, further comprising:
engaging a set of flex connections with the first circuit card, the second circuit card, the third circuit card, and the fourth circuit card;
wherein the set of flex connections interconnects the first circuit card, the second circuit card, the third circuit card, and the fourth circuit card with one another.

20. The method of claim 17, further comprising:
engaging the top plate with the internal support and the flexible control CCA by a set of connectors.
